(19) United States
(12) Patent Application Publication
(10) Pub. No.: US 2023/0168286 A1
(43) Pub. Date: Jun. 1, 2023

(54) REVERBERATION CHAMBER AND ANTENNA DEVICE

(71) Applicant: TDK Corporation, Tokyo (JP)

(72) Inventors: Masataka MIDORI, Tokyo (JP); Shotaro HAMAMOTO, Tokyo (JP); Hiroshi KURIHARA, Tokyo (JP)

(73) Assignee: TDK Corporation, Tokyo (JP)

(21) Appl. No.: 17/992,411

(22) Filed: Nov. 22, 2022

(30) Foreign Application Priority Data
Nov. 29, 2021 (JP) 2021-193482

(51) Int. Cl. G01R 29/08

(52) U.S. Cl. CPC G01R 29/0821; G01R 29/0864

(57) ABSTRACT

A reverberation chamber capable of performing an EMS test having high accuracy in a wider frequency band is provided. There is provided a reverberation chamber including an electromagnetic stirrer, in which the electromagnetic stirrer includes: a first stirring blade; and a holding body disposed on a first wall face of the reverberation chamber, extending in a first direction intersecting with the first wall face, and configured to hold the first stirring blade, and the first stirring blade is electrically insulated from the first wall face.

### BACKGROUND OF THE INVENTION

### Field of the Invention

The present invention relates to a reverberation chamber and an antenna device.

Priority is claimed on Japanese Patent Application No. 2021-193482, filed Nov. 29, 2021, the content of which is incorporated herein by reference.

### Description of Related Art

Technologies for performing an EMS (Electromagnetic Susceptivity) test that is an electromagnetic wave-resistance test for a vehicle, an electronic device mounted in a vehicle, and the like using a reverberation chamber have been researched and developed.

A reverberation chamber is composed of a cavity resonator made of metal and an electromagnetic stirrer. The cavity resonator is responsible for generating an electric field using a resonance phenomenon in a reverberation chamber. In a distribution of an intensity of an electric field generated by a cavity resonator, variations in the intensity due to a size of the cavity resonator appear. In other words, the distribution of the intensity of an electric field generated by a cavity resonator becomes a nonuniform distribution. For this reason, the electromagnetic stirrer stirs electromagnetic waves inside the cavity resonator, and reduces the distribution of the intensity of the electric field generated by the cavity resonator close to a uniform distribution. By applying this to an EMS test, an electric field of which an intensity is uniform can be emitted to a device under test, and thus the reverberation chamber becomes a test device having high test quality.

In such a reverberation chamber, it is known that a resonance frequency of the cavity resonator is in inverse proportion to the size of the resonator. For this reason, in an EMS test, as the frequency of an electric field generated using a resonance phenomenon becomes lower, the volume of the reverberation chamber needs to be larger.

Here, for example, in an EMS test of a vehicle performed in an anechoic chamber, an electric field of a frequency band including a frequency of about 10 kHz is emitted to the vehicle. In a case in which an EMS test using an electric field of such a frequency band is performed inside a reverberation chamber, the size of the reverberation chamber becomes about 10 km. A reverberation chamber of such a size restricts a degree of freedom of an installation place and thus is not desirable. For this reason, in recent years, it has come to be desired that a reverberation chamber be a device capable of performing an EMS test using this frequency band, and have a size such that a device under test can be put therein.

Inside an anechoic chamber, as a test device emitting an electric field of a predetermined low frequency band to a device under test, a test device (a strip line device) called a TSL (Transmission Line System) is known (see Patent Document 1). The low frequency band is a frequency band including a frequency that is equal to or lower than a lowest frequency (a lowest usable frequency (LUF)) for functioning as a reverberation chamber, a frequency band including a frequency lower than a resonance frequency of a lowest order of the reverberation chamber, or the like.

### Patent Documents

[Patent Document 1] Japanese Unexamined Patent Application, First Publication No. 2013-072786

### SUMMARY OF THE INVENTION

In addition, as a test device that emits an electric field of a such a low frequency band to a device under test in an anechoic chamber, a test device emitting an electric field from an antenna such as a log-periodic antenna and the like are known. Each of such test devices can emit an electric field of this low frequency band to a device under test as an electric field of which the intensity is uniform inside an anechoic chamber.

However, in a case in which such a test device is used inside a reverberation chamber, an electric field of a frequency lower than a resonance frequency of the lowest order of the reverberation chamber may cause a resonance phenomenon to occur although the frequency is a frequency lower than the resonance frequency of the lowest order of the reverberation chamber. This leads to non-uniformity of the intensity of the electric field and thus is not desirable. In addition, in a case in which the frequency of an electric field is lower than the resonance frequency of the lowest order of the reverberation chamber, the electromagnetic stirrer cannot stir the electric field. For this reason, in this case, it is difficult for the reverberation chamber to decrease variations of the intensity of the electric field using the electromagnetic stirrer.

The present invention is in consideration of such situations, and an object thereof is to provide a reverberation chamber and an antenna device capable of performing an EMS test having high accuracy in a wider frequency band.

According to one aspect of the present invention, there is provided a reverberation chamber including an electromagnetic stirrer, in which the electromagnetic stirrer includes: a first stirring blade; and a holding body disposed on a first wall face of the reverberation chamber, extending in a first direction intersecting with the first wall face, and configured to hold the first stirring blade, and the first stirring blade is electrically insulated from the first wall face.

In addition, according to one aspect of the present invention, there is provided a reverberation chamber including an electromagnetic stirrer, in which the electromagnetic stirrer includes: a first stirring blade; a second stirring blade; and a holding body disposed on a first wall face of the reverberation chamber, extending in a first direction intersecting with the first wall face, configured to hold the first stirring blade and the second stirring blade to be aligned in the first direction, and the first stirring blade is electrically insulated from the second stirring blade.

Furthermore, according to one aspect of the present invention, there is provided an antenna device including the reverberation chamber described above.

According to the present invention, an EMS test having high accuracy can be performed in a wider frequency band.

### BRIEF DESCRIPTION OF THE DRAWINGS

FIG. 1 is a diagram illustrating an example of a configuration of a reverberation chamber 1 according to an embodiment.

FIG. 2 is a diagram illustrating Configuration example 1 of an electromagnetic stirrer 13.

FIG. 3 is a diagram illustrating an example of a configuration of a coupling C1.

FIG. 4 is a diagram illustrating another example of the configuration of the coupling C1.

FIG. 5 is a diagram illustrating further another example of the configuration of the coupling C1.

FIG. 6 is a diagram illustrating an example of a configuration of a bearing B1.

FIG. 7 is a diagram illustrating another example of the configuration of the bearing B1.

FIG. 8 is a diagram illustrating further another example of the configuration of the bearing B1.

FIG. 9 is a diagram illustrating an example of a gap SP formed in a first stirring blade 131.

FIG. 10 is a diagram illustrating an example of an appearance of the first stirring blade 131 fixed to a flange F1.

FIG. 11 is a diagram illustrating another example of the appearance of the first stirring blade 131 fixed to the flange F1.

FIG. 12 is a diagram illustrating further another example of the appearance of the first stirring blade 131 fixed to the flange F1.

FIG. 13 is a diagram illustrating an electric field intensity inside the reverberation chamber 1 acquired in a case in which a conventional electromagnetic stirrer is included in the reverberation chamber 1 in place of the electromagnetic stirrer 13A.

FIG. 14 is a diagram illustrating an electric field intensity of the inside of the reverberation chamber 1.

FIG. 15 is a diagram illustrating Configuration example 2 of the electromagnetic stirrer 13.

FIG. 16 is a diagram illustrating Configuration example 3 of the electromagnetic stirrer 13.

FIG. 17 is a diagram illustrating Configuration example 4 of the electromagnetic stirrer 13.

FIG. 18 is a diagram illustrating Configuration example 5 of the electromagnetic stirrer 13.

FIG. 19 is a diagram illustrating Configuration example 6 of the electromagnetic stirrer 13.

FIG. 20 is a diagram illustrating Configuration example 7 of the electromagnetic stirrer 13.

FIG. 21 is a diagram illustrating Modified example 1 of a configuration of a support body SB illustrated in FIG. 20.

FIG. 22 is a diagram illustrating Modified example 2 of the configuration of the support body SB illustrated in FIG. 20.

FIG. 23 is a diagram illustrating Modified example 3 of the configuration of the support body SB illustrated in FIG. 20.

FIG. 24 is a diagram illustrating Configuration example 8 of the electromagnetic stirrer 13.

FIG. 25 is a diagram illustrating Configuration example 9 of the electromagnetic stirrer 13.

FIG. 26 is a table illustrating a list of materials used in a bush made of an insulator such as a bush BS2, a screw (or a bolt) made of an insulator such as a fixing tool SC, a spacer made of an insulator such as a spacer S1, a stand made of an insulator such as a bearing fixing stand B13, and the like.

FIG. 27 is a table illustrating a list of materials used in a bearing of which an entirety thereof is configured using an insulator such as a bearing B1 illustrated in FIG. 6.

FIG. 28 is a table illustrating a list of materials used for coating of a bearing B1 illustrated in FIG. 7 with an insulator.

FIG. 29 is a table illustrating a list of materials used for a holding body A1 made of an insulator and the like.

### DETAILED DESCRIPTION OF THE INVENTION

### Embodiment

Hereinafter, an embodiment of the present invention will be described with reference to the drawings. Hereinafter, for the convenience of description, an intensity of an electric field will be referred to as an electric field intensity in description. For this reason, hereinafter, an intensity of an electric field inside a certain area will be referred to as an electric field intensity of the inside of the area in description.

### Configuration of Reverberation Chamber

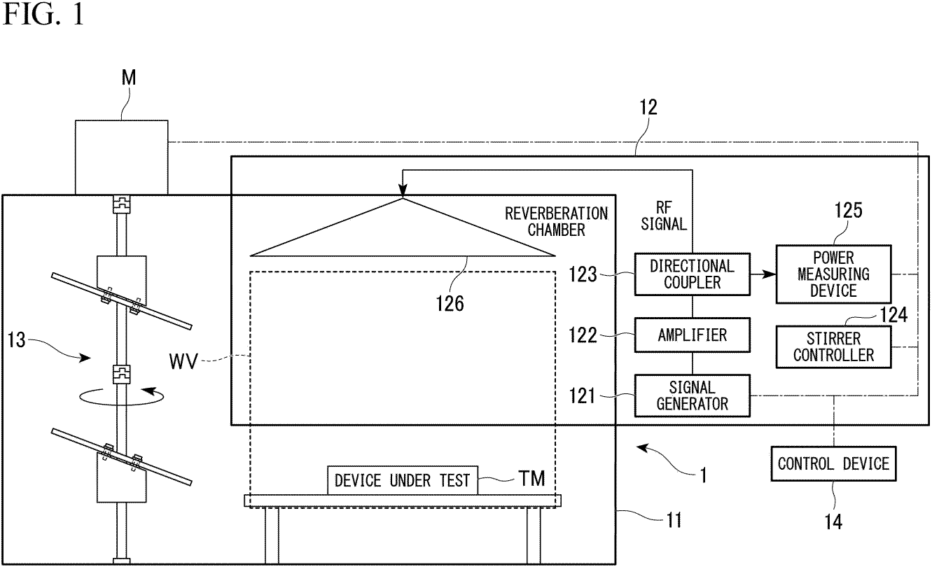

First, a configuration of a reverberation chamber 1 according to an embodiment will be described with reference to FIG. 1. FIG. 1 is a diagram illustrating an example of a configuration of the reverberation chamber 1 according to the embodiment.

A reverberation chamber 1 is a container in which EMS tests for various electronic devices are performed inside thereof. Hereinafter, for the convenience of description, an electronic device that is a target for an EMS test will be referred to as a device under test in description.

In an EMS test, an electromagnetic environment in which a device under test is estimated to be actually used is generated in a pseudo manner. Then, in an EMS test, it is tested whether or not a device under test operates normally in the generated electromagnetic environment. In such an EMS test, as uniformity of an electric field intensity inside an area including a device under test becomes higher, a test result having higher accuracy can be acquired. Here, the uniformity of an electric field intensity inside a certain area is represented using an amount representing a deviation of the electric field intensity inside this area (for example, a standard deviation, a dispersion, or the like). In other words, as the amount representing a deviation of the electric field intensity inside this area becomes smaller, the uniformity of the electric field intensity inside the area becomes higher.

For example, the reverberation chamber 1 includes a cavity resonator 11, a test device 12, and an electromagnetic stirrer 13. In addition, the reverberation chamber 1 may be configured not to include the test device 12. In addition, although the test device 12 is integrally configured with the reverberation chamber 1 in FIG. 1, the reverberation chamber 1 may be configured as a body separate from the test device 12. In a case in which the reverberation chamber 1 and the test device 12 are configured as separate bodies, the reverberation chamber 1 configures an antenna device together with the test device 12. In addition, the reverberation chamber 1 may be configured to include other members, other devices, and the like in addition to the cavity resonator 11, the test device 12, and the electromagnetic stirrer 13.

The cavity resonator 11 is a casing made of metal that can house a device under test. The cavity resonator 11 causes an electric field of frequencies equal to or higher than a resonance frequency of the lowest order of the reverberation chamber 1 to resonate. In the cavity resonator 11, a part of a wall face inside the cavity resonator 11 may be configured using an insulator. Hereinafter, for the convenience of description, the resonance frequency of the lowest order of the reverberation chamber 1 will be referred to as a lowest-order resonance frequency in description.

The test device 12 is a device that emits an electric field of a predetermined frequency band to a device under test disposed inside the cavity resonator 11. The test device 12 is connected to the control device 14 such that they are able to communicate with each other and is controlled by the control device 14. In the example illustrated in FIG. 1, the test device 12 is configured as a body separate from the control device 14. However, the test device 12 may be configured integrally with the control device 14.

For example, the control device 14 is a laptop PC (Personal Computer), a desktop PC, a workstation, a tablet PC, a multi-function mobile phone terminal (a smartphone), a mobile phone terminal, a PDA (Personal Digital Assistant), or the like but is not limited thereto. The control device 14 accepts an operation from a user and controls the test device 12 in accordance with the accepted operation.

The test device 12 includes a signal generator 121, an amplifier 122, a directional coupler 123, a stirrer controller 124, a power measuring device 125, and an antenna 126.

The signal generator 121 outputs an AC voltage signal of a predetermined frequency to the amplifier 122 in accordance with control from the control device 14. Hereinafter, as an example, a case in which the signal generator 121 outputs an AC voltage signal of a frequency lower than a lowest-order resonance frequency to the amplifier 122 will be described.

The amplifier 122 amplifies an amplitude of an AC voltage signal acquired from the signal generator 121 and outputs an AC voltage signal after amplification of the amplitude to the directional coupler 123.

The directional coupler 123 outputs an AC voltage signal acquired from the amplifier 122 to the power measuring device 125 and outputs the AC voltage signal to the antenna 126 as an RF signal.

The stirrer controller 124 outputs a control signal for controlling a motor M rotating the electromagnetic stirrer 13 to the motor M in accordance with electric power measured by the power measuring device 125 and control from the control device 14.

The power measuring device 125 measures electric power based on an AC voltage signal acquired from the directional coupler 123. The power measuring device 125 outputs power information representing the measured electric power to the control device 14.

The antenna 126 emits an electric field according to an RF signal acquired from the directional coupler 123 to a device under test. The antenna 126 is installed at a position at which the electric field can be emitted to a device under test. In this example, a frequency of the RF signal is a frequency lower than the lowest-order resonance frequency. In this case, the antenna 126 emits an electric field of a frequency lower than the lowest-order resonance frequency to a device under test.

In the example illustrated in FIG. 1, the antenna 126 is installed in an area immediately above a work area WV in a ceiling face of the cavity resonator 11. The work area WV is an area in which a device under test is installed in an area inside the cavity resonator 11. In other words, the work area WV is an area in which an EMS test is performed in an internal area of the reverberation chamber 1. In the example illustrated in FIG. 1, inside the work area WV, a device under test TM is disposed. The device under test TM represents an example of an electronic device serving as a device under test.

The electromagnetic stirrer 13 stirs electromagnetic waves inside the reverberation chamber 1. In accordance with this, the reverberation chamber 1 can decrease variation of the electric field intensity inside the work area WV.

The electromagnetic stirrer 13 includes one or more stirring blades and is rotated using a motor M. The motor M rotating the electromagnetic stirrer 13 may be configured to be included in the reverberation chamber 1, may be configured to be included in the electromagnetic stirrer 13, or may be configured not to be included in the reverberation chamber 1 and the electromagnetic stirrer 13. In FIG. 1, in order to simplify the drawing, various mechanisms, various gears, and the like transferring a drive force of the motor M to the electromagnetic stirrer 13 are omitted.

Here, although an electric field of a frequency lower than the lowest-order resonance frequency has the frequency lower than the lowest-order resonance frequency, the electric field may cause a resonance phenomenon inside the reverberation chamber 1. This leads to the uniformity of the electric field intensity of the inside of the work area WV being lost, which is not desirable. Such a resonance phenomenon occurs in accordance with the electromagnetic stirrer 13 functioning as a capacitor, a combination of the electromagnetic stirrer 13 and the cavity resonator 11 functioning as a capacitor, and the like. For example, in a case in which the electromagnetic stirrer 13 has only one stirring blade, a space between the one stirring blade and a wall face of the inside of the cavity resonator 11 functions as a capacitor. In other words, in this case, a combination of the electromagnetic stirrer 13 and the cavity resonator 11 functions as a capacitor. In addition, for example, in a case in which the electromagnetic stirrer 13 has two or more stirring blades, a space between these two or more stirring blades and the wall face of the inside of the cavity resonator 11 functions as a capacitor, and a space between these two or more stirring blades also functions as a capacitor. In other words, in this case, the combination of the electromagnetic stirrer 13 and the cavity resonator 11 functions as a capacitor, and the electromagnetic stirrer 13 also functions as a capacitor.

The presence of such capacitors causes an LC resonance phenomenon to occur. For example, in a case in which a space between a certain stirring blade and a certain wall face of the inside of the cavity resonator 11 functions as a capacitor, a member connecting this stirring blade and this wall face functions as an inductor, and an LC resonance circuit is formed. In addition, for example, in a case in which a space between certain two stirring blades functions as a capacitor, a member connecting these two stirring blades functions as an inductor, and an LC resonance circuit is formed. In accordance with a resonance phenomenon of the LC resonance circuit formed in this way, a distribution of the electric field intensity of a frequency lower than the lowest-order resonance frequency may be a non-uniform distribution.

Thus, by including at least one of a configuration insulating stirrers from each other and a configuration insulating the wall face of the inside of the cavity resonator 11 and the stirrer from each other, the electromagnetic stirrer 13 inhibits an occurrence of at least a part of the resonance phenomenon according to such an LC resonance circuit. In accordance with this, the reverberation chamber 1 including the electromagnetic stirrer 13 can cause the distribution of an electric field intensity inside the work area WV to be close to uniformity in a wider frequency band. As a result, the reverberation chamber 1 can perform an EMS test in a wider frequency band with high accuracy. In addition, the reverberation chamber 1 can generate an electric field of which an electric field intensity is uniform inside the work area WV using the test device 12 described above without increasing the volume of the reverberation chamber 1. Thus, the reverberation chamber 1 including the test device 12 and the electromagnetic stirrer 13 (or the antenna device including the test device 12, and the reverberation chamber 1 including the electromagnetic stirrer 13) can perform an EMS test with high accuracy in a wider frequency band without increasing the volume of the cavity resonator 11.

Hereinafter, a specific example of the configuration of the electromagnetic stirrer 13 will be described.

### Configuration Example 1 of Electromagnetic Stirrer

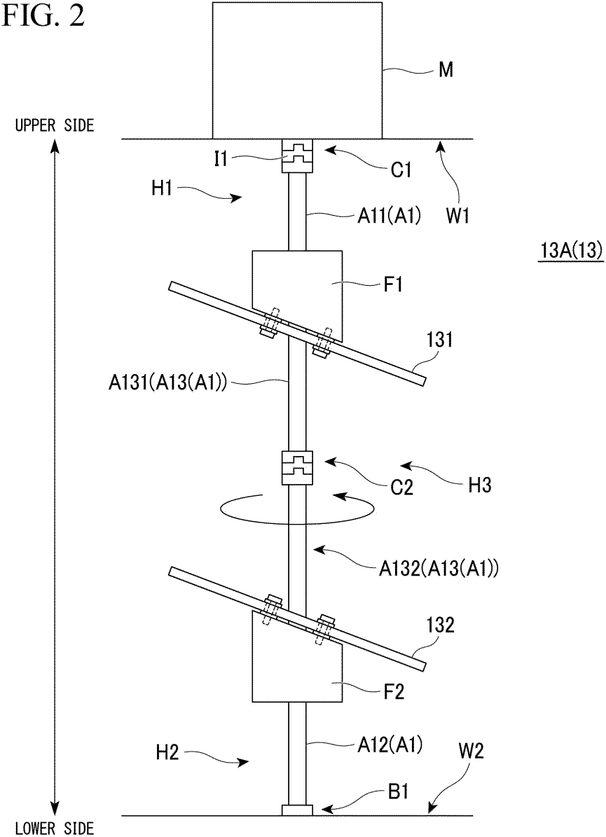

Hereinafter, Configuration example 1 of the electromagnetic stirrer 13 will be described with reference to FIG. 2. FIG. 2 is a diagram illustrating Configuration example 1 of the electromagnetic stirrer 13. Hereinafter, for the convenience of description, the electromagnetic stirrer 13 illustrated in FIG. 2 will be referred to as an electromagnetic stirrer 13A in description. An arrow illustrated in FIG. 2 represents upward/downward directions in FIG. 2. The upward direction represented by this arrow represents a direction opposite to the direction of gravity. In addition, the downward direction represented by this arrow represents the direction of gravity. Furthermore, hereinafter, as an example, a case in which the electromagnetic stirrer 13A includes two stirring blades will be described.

The electromagnetic stirrer 13A is installed between two faces including a first wall face W1 and a second wall face W2 among face walls of the inside of the cavity resonator 11.

The first wall face W1 may be any wall face as long as it is a wall face of the inside of the cavity resonator 11. In the example illustrated in FIG. 2, the first wall face W1 is a wall face on an upper side among wall faces of the inside of the cavity resonator 11, that is, a ceiling face of the inside of the cavity resonator 11.

The second wall face W2 may be any wall face as long as it is a wall face different from the wall face used as the first wall face W1 among wall faces of the inside of the cavity resonator 11. In the example illustrated in FIG. 2, the second wall face W2 is a wall face on a lower side among wall faces of the inside of the cavity resonator 11, that is, a floor face of the inside of the cavity resonator 11. In addition, in a case in which the electromagnetic stirrer 13 is rotated using a motor M through a universal joint and the like, the second wall face W2 may be the same wall face as the first wall face W1.

In the example illustrated in FIG. 2, the electromagnetic stirrer 13A is installed such that a rotation shaft of the electromagnetic stirrer 13A (in other words, a rotation shaft A0 of the motor M) is in parallel with the direction of gravity between two faces including the first wall face W1 and the second wall face W2.

The electromagnetic stirrer 13A includes a holding body A1, a first stirring blade 131, a flange F1, a second stirring blade 132, a flange F2, a coupling C1, a coupling C2, and a bearing B1.

For example, the holding body A1 is a shaft body made of metal that extends in a first direction. The first direction is a direction parallel to a shaft direction of the rotation shaft of the electromagnetic stirrer 13A rotated in accordance with driving of the motor M. In the example illustrated in FIG. 2, the first direction is a direction from the first wall face W1 to the second wall face W2, that is, a direction of gravity among directions orthogonal to the first wall face W1. The holding body A1 may be composed of a plurality of shaft members or may be composed of a single shaft member. In addition, the holding body A1 may be made of a conductor other than metal in place of the metal.

The first stirring blade 131, the second stirring blade 132, the coupling C1, the coupling C2, and the bearing B1 are aligned and fixed to the holding body A1 in order of the coupling C1, the first stirring blade 131, the coupling C2, the second stirring blade 132, and the bearing B1 from top to bottom.

Hereinafter, for the convenience of description, a combination of a part A11 positioned on an upper side of the first stirring blade 131 among parts included in the holding body A1, the coupling C1, and the flange F1 will be referred to as a holding body H1 in description. In addition, hereinafter, for the convenience of description, a combination of a part A12 positioned on a lower side of the second stirring blade 132 among parts included in the holding body A1, the bearing B1, and the flange F2 will be referred to as a holding body H2 in description. Furthermore, hereinafter, for the convenience of description, a combination of a part A13 positioned between the first stirring blade 131 and the second stirring blade 132 among parts included in the holding body A1 and the coupling C2 will be referred to as a holding body H3 in description. At least one of the holding body H1 to the holding body H3 may be configured as separate bodies or may be integrally configured as one body.

The part A11 is connected to the rotation shaft A0 of the motor M through the coupling C1 included in the holding body H1. For this reason, the holding body A1 rotates in accordance with rotation of the rotation shaft A0 of the motor M. In the example illustrated in FIG. 2, for the simplification of the drawing, the rotation shaft A0 of the motor M is omitted. The holding body H1 may be configured to include the rotation shaft A0 of the motor M. In such a case, the rotation shaft A0 of the motor M is an example of a third holding body that is electrically connected to the first wall face. In addition, in such a case, the part A11 is an example of a fourth holding body that is connected to the first stirring blade. In addition, the holding body H1 may be configured to include a member (for example, a shaft member or the like) that connects the rotation shaft A0 of the motor M and the coupling C1. In such a case, this member is an example of the third holding body that is electrically connected to the first wall face. In addition, in such a case, the part A11 is an example of the fourth holding body that is connected to the first stirring blade.

The coupling C1 is a coupling that connects the rotation shaft A0 of the motor M and the part A11.

The flange F1 is a flange made of metal to which the first stirring blade 131 is fixed and may be a flange of any shape. The flange F1 is fixed to the part A11 using a fixing tool such as a screw. In addition, the flange F1 may be configured integrally with the part A11. Furthermore, the flange F1 may be configured separately from the holding body H1. In addition, the flange F1 may be configured to be included in the holding body H3 instead of the holding body H1. In such a case, the first stirring blade 131 is held by the holding body H3. In addition, the flange F1 may be a conductor other than metal in place of the metal.

For example, the first stirring blade 131 is a rectangular flat plate-shaped member made of metal. The first stirring blade 131 is held in the holding body H1 through the flange F1. In other words, the first stirring blade 131 is fixed to the flange F1. In addition, the electromagnetic stirrer 13A may be configured not to include the flange F1. In such a case, the first stirring blade 131 is fixed to the part A11, thereby being held in the holding body H1. The first stirring blade 131 may be configured integrally with at least a part of a member configuring the holding body H1. In addition, the first stirring blade 131 may be made of a conductor other than metal in place of the metal.

In a case in which the shape of the first stirring blade 131 is a rectangular flat plate shape, the first stirring blade 131 is fixed to the flange F1 such that it obliquely intersects with the holding body A1. In accordance with this, the first stirring blade 131 can stir electromagnetic waves inside the cavity resonator 11 in accordance with rotation of the electromagnetic stirrer 13A. The shape of the first stirring blade 131 may be another shape instead of the rectangular flat plate shape. In such a case, the first stirring blade 131 is fixed to the flange F1 such that it can stir electromagnetic waves inside the cavity resonator 11 in accordance with rotation of the electromagnetic stirrer 13A.

The part A13 is divided into two vertically-divided parts. These two parts are connected using the coupling C2. Hereinafter, for the convenience of description, an upper part among these two parts will be referred to as a holding body A131, and a lower part among these two parts will be referred to as a holding body A132 in description.

The coupling C2 is a coupling that connects the holding body A131 and the holding body A132.

The holding body A131 is connected to the part A11. The holding body A131 may be configured integrally with the part A11 or may be configured separately from the part A11. In a case in which the holding body A131 is configured separately from the part A11, the holding body A1 includes a coupling or the like that connects the holding body A131 and the part A11.

The holding body A132 is connected to the part A12. The holding body A132 may be configured integrally with the part A12 or may be configured separately from the part A12. In a case in which the holding body A132 is configured separately from the part A12, the holding body A1 includes a coupling or the like that connects the holding body A132 and the part A12.

The part A12 is connected to the second wall face W2 through the bearing B1. For this reason, the second wall face W2 does not block rotation of the holding body A1 using the motor M.

The bearing B1 is a thrust bearing that receives the holding body A1 rotating around the rotation shaft of the motor M.

The flange F2 is a flange made of metal to which the second stirring blade 132 is fixed and may be a flange of any shape. The flange F2 is fixed to the part A12 using a fixing tool such as a screw. In addition, the flange F2 may be configured integrally with the part A12. Furthermore, the flange F2 may be configured separately from the holding body H2. In addition, the flange F2 may be configured to be included in the holding body H3 instead of the holding body H2. In such a case, the second stirring blade 132 is held by the holding body H3. In addition, the flange F2 may be a conductor other than metal in place of the metal.

For example, the second stirring blade 132 is a rectangular flat plate-shaped member made of metal. The second stirring blade 132 is held in the holding body H2 through the flange F2. In other words, the second stirring blade 132 is fixed to the flange F2. In addition, the electromagnetic stirrer 13A may be configured not to include the flange F2. In such a case, the second stirring blade 132 is fixed to the part A12, thereby being held in the holding body H2. The second stirring blade 132 may be configured integrally with at least a part of a member configuring the holding body H2. In addition, the second stirring blade 132 may be made of a conductor other than metal in place of the metal.

In a case in which the shape of the second stirring blade 132 is a rectangular flat plate shape, the second stirring blade 132 is fixed to the flange F2 such that it obliquely intersects with the holding body A1. In accordance with this, the second stirring blade 132 can stir electromagnetic waves inside the cavity resonator 11 in accordance with rotation of the electromagnetic stirrer 13A. The shape of the second stirring blade 132 may be another shape instead of the rectangular flat plate shape. In such a case, the second stirring blade 132 is fixed to the flange F2 such that it can stir electromagnetic waves inside the cavity resonator 11 in accordance with rotation of the electromagnetic stirrer 13A.

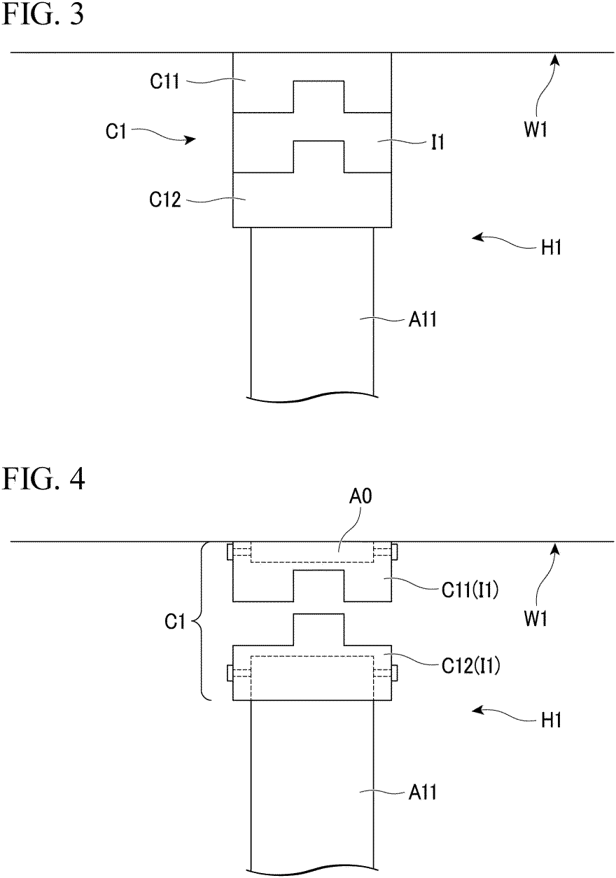

In the electromagnetic stirrer 13A having the configuration as described above, the holding body H1 includes an insulator I1 that electrically insulates the first stirring blade 131 and the first wall face W1 from each other. In other words, the electromagnetic stirrer 13A includes the insulator I1. For example, as illustrated in FIG. 3, the insulator 11 is a part of the coupling C1.

FIG. 3 is a diagram illustrating an example of a configuration of the coupling C1.

For example, the coupling C1 is composed of a first member C11, an insulator 11, and a second member C12.

For example, the first member C11 is a member made of metal having a concave part fitted to a convex part of the insulator I1 and is a member fixed to the rotation shaft A0 of the motor M using a fixing tool such as a screw. In FIG. 3, for simplification of the drawing, the rotation shaft A0 of the motor M and the fixing tool are omitted. The shapes of the convex part of the insulator I1 and the concave part of the first member C11 may be any shapes as long as the shapes enable rotation of the insulator I1 according to rotation of the first member C11 in a case in which the convex part and the concave part are fitted to each other. In the example illustrated in FIG. 3, the first member C11 is in contact with the first wall face W1. However, the first member C11 may be configured to be separate from the first wall face W1. In addition, the first member C11 may be made of a conductor other than metal in place of the metal.

For example, the insulator I1 is a member made of an insulator that has a convex part fitted to the concave part of the first member C11 and a concave part fitted to the convex part of the second member C12 and is a member that rotates in accordance with rotation of the first member C11. For example, the insulator I1 is a resin but is not limited to the resin. The shapes of the convex part of the second member C12 and the concave part of the insulator 11 may be any shapes as long as the shapes enable rotation of the second member C12 according to rotation of the insulator 11 in a case in which the convex part and the concave part are fitted to each other.

For example, the second member C12 is a member made of metal having a convex part fitted to the concave part of the insulator I1 and is a member that rotates in accordance with rotation of the first member C11 and the insulator I1. For example, the second member C12 is fixed to the part A11 using a fixing tool such as a screw. In FIG. 3, for simplification of the drawing, this fixing tool is omitted. In addition, the second member C12 may be made of a conductor other than metal in place of the metal.

In this way, the insulator I1 is included in the holding body H1 as a part of the coupling C1, whereby each of the first stirring blade 131 and the second stirring blade 132 is electrically insulated from the first wall face W1. In accordance with this, the reverberation chamber 1 can inhibit a space between each of the first stirring blade 131 and the second stirring blade 132 and the first wall face W1 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

In addition, as illustrated in FIG. 4, the insulator 11 may configure the entire coupling C1. FIG. 4 is a diagram illustrating another example of the configuration of the coupling C1. In the example illustrated in FIG. 4, the coupling C1 is composed of two members including the first member C11 and the second member C12. In this example, each of these two members is configured using the insulator 11. In FIG. 4, different from FIG. 3, a rotation shaft A0 of a motor M and a fixing tool fixing a first member C11 to the rotation shaft A0 of the motor M are not omitted and illustrated. In FIG. 4, an appearance in which the first member C11 and the second member C12 are separate from each other is drawn. However, in a case in which the electromagnetic stirrer 13A is rotated by the motor M, the first member C11 and the second member C12 are fitted to each other.

Also in a case in which the entire coupling C1 is composed of the insulator I1, in the reverberation chamber 1, each of the first stirring blade 131 and the second stirring blade 132 is electrically insulated from the first wall face W1. In accordance with this, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

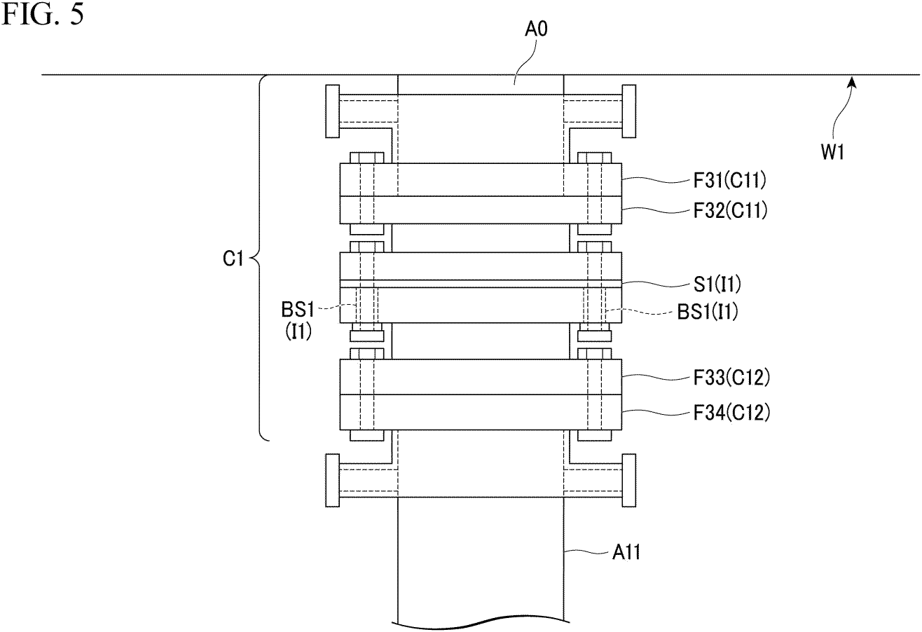

In addition, as illustrated in FIG. 5, the insulator I1 may configure a part of the coupling C1. FIG. 5 is a diagram illustrating further another example of the configuration of the coupling C1. In the example illustrated in FIG. 5, the coupling C1 is composed of a first member C11, a second member C12, a spacer S1 disposed between the first member C11 and the second member C12, and a plurality of bushes BS1 made of insulators. In this example, the spacer S1 and each of the plurality of bushes BS1 are composed of insulators I1. In addition, in this example, the first member C11 is composed of two flanges including a flange F31 and a flange F32. In this example, the second member C12 is composed of two flanges including a flange F33 and a flange F34.

The flange F31 is a flange made of metal that is fixed to a rotation shaft A0 of a motor M using a fixing tool such as a screw. In addition, the flange F31 may be made of a conductor other than metal in place of the metal.

The flange F32 is a flange made of metal that is fixed to the flange F31 using a fixing tool such as a screw. For this reason, the flange F32 rotates together with the flange F31 in accordance with rotation of the flange F31. In addition, the flange F32 may be made of a conductor other than metal in place of the metal.

The flange F33 is a flange made of metal that is fixed to the flange F32 using a fixing tool such as a screw. For this reason, the flange F33 rotates together with the flange F32 in accordance with rotation of the flange F32. In addition, the flange F33 may be made of a conductor other than metal in place of the metal.

Between the flange F32 and the flange F33, the spacer S1 made of an insulator is disposed. In addition, in the flange F32 and the flange F33, a plurality of openings through which fixing tools such as screws fixing the flange F32 and the flange F33 pass are formed. Among the plurality of openings, in each of openings formed in the flange F33, a flange bush made of an insulator that is buried between the fixing tool and the flange F33 inside the opening is inserted as a bush BS1. The bush BS1 that is a flange bush is buried between the fixing tool and the flange F33 using a flange part of the flange bush also outside the opening which the fixing tool is inserted in and passes through. For this reason, even in a case in which the flange F32 and the flange F33 are fixed using the fixing tool, the fixing tool is not in contact with the flange F33. In other words, also in this case, the fixing tool is electrically insulated from the flange F33.

The flange F14 is a flange made of metal that is fixed to the flange F13 using a fixing tool such as a screw. For this reason, the flange F14 rotates together with the flange F13 in accordance with rotation of the flange F13. In addition, the flange F14 is fixed to the part A11 using a fixing tool such as a screw. In addition, the flange F14 may be made of a conductor other than metal in place of the metal.

In a case in which the configuration of the coupling C1 is a configuration as illustrated in FIG. 5, the first member C11 and the second member C12 are electrically insulated from each other in accordance with the spacer S1 and the plurality of bushes BS1. In accordance with this, also in this case, each of the first stirring blade 131 and the second stirring blade 132 is electrically insulated from the first wall face W1. Thus, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

In addition, in the electromagnetic stirrer 13A, the holding body H3 includes an insulator I2 that electrically insulates the first stirring blade 131 and the second stirring blade 132 from each other. In other words, the electromagnetic stirrer 13A includes an insulator I2. For example, the insulator I2 is configured as a part or the entirety of the coupling C2. The configuration of the coupling C2 of which a part or the entirety is configured using the insulator 12 is a configuration similar to the configuration of the coupling C1 described with reference to FIGS. 3 to 5 except that a target to which the coupling C2 is connected is not the rotation shaft A0 of the motor M and the part A11 but the holding body A131 and the holding body A132. For this reason, detailed description of the configuration of the coupling C2 will be omitted.

By including the insulator 12 in the electromagnetic stirrer 13A, each of the first stirring blade 131 and the second stirring blade 132 is electrically insulated from the second wall face W2. In accordance with this, the reverberation chamber 1 can inhibit a space between each of the first stirring blade 131 and the second stirring blade 132 and the second wall face W2 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

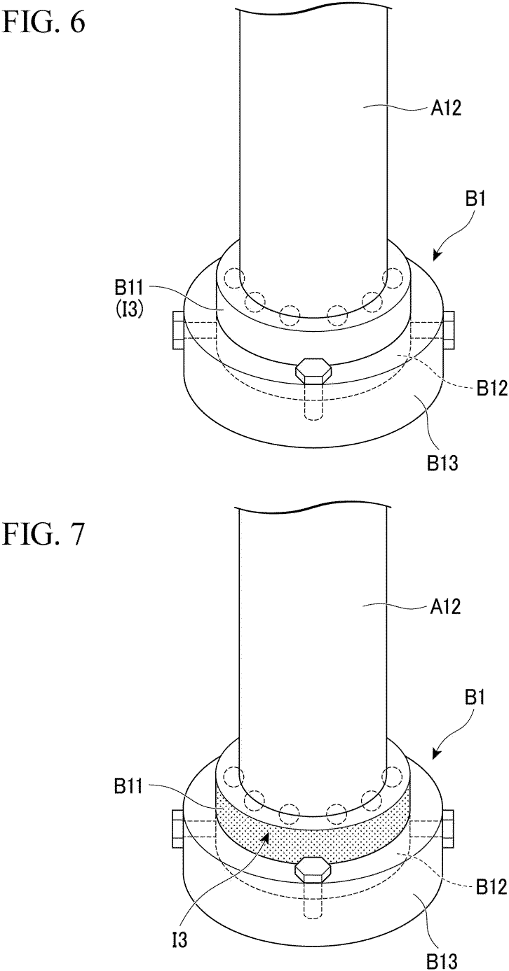

In addition, in the electromagnetic stirrer 13A, the holding body H2 includes an insulator I3 that electrically insulates the second wall face W2 and the second stirring blade 132 from each other. In other words, the electromagnetic stirrer 13A includes the insulator 13. For example, as illustrated in FIG. 6, the insulator 13 is a part of the bearing B1.

FIG. 6 is a diagram illustrating an example of a configuration of the bearing B1. In FIG. 6, for simplification of the drawing, the second wall face W2 is omitted.

The bearing B1 includes a housing bearing washer B11, a shaft bearing washer B12, a plurality of metal spheres, which are not illustrated, interposed between the housing bearing washer B11 and the shaft bearing washer B12, and a bearing fixing stand B13 that fixes the shaft bearing washer B12 to the second wall face W2. The bearing fixing stand B13 is fixed to the second wall face W2 using a fixing tool such as a screw.

In the example illustrated in FIG. 6, the housing bearing washer B11 is configured using the insulator 13. In accordance with this, each of the first stirring blade 131 and the second stirring blade 132 is electrically insulated from the second wall face W2. In accordance with this, the reverberation chamber 1 can inhibit a space between each of the first stirring blade 131 and the second stirring blade 132 and the second wall face W2 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In this example, at least one of the shaft bearing washer B12, the plurality of metal spheres, and the bearing fixing stand B13 may be made of metal, a conductor other than metal, or an insulator.

In addition, as illustrated in FIG. 7, the insulator 13 may be a coating made of ceramic that coats the surface of the housing bearing washer B11. FIG. 7 is a diagram illustrating another example of the configuration of the bearing B1. In FIG. 7, for simplification of the drawing, the second wall face W2 is omitted. In FIG. 7, the insulator I3 coating the surface of the housing bearing washer B11 as a coating is illustrated using hatching. Also in a case in which the surface of the housing bearing washer B11 is coated with the insulator 13 as a coating, each of the first stirring blade 131 and the second stirring blade 132 is electrically insulated from the second wall face W2. In other words, also in this case, the reverberation chamber 1 can inhibit a space between each of the first stirring blade 131 and the second stirring blade 132 and the second wall face W2 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, in the example illustrated in FIG. 7, at least one of the shaft bearing washer B12, the plurality of metal spheres, and the bearing fixing stand B13 may be made of metal, a conductor other than metal, or an insulator.

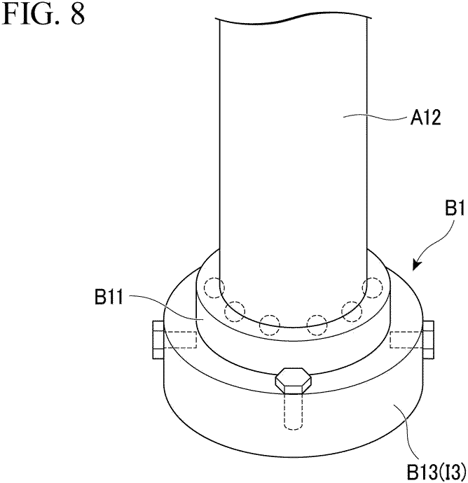

In addition, as illustrated in FIG. 8, the insulator 13 may be the bearing fixing stand B13. FIG. 8 is a diagram illustrating further another example of the configuration of the bearing B1. In FIG. 8, for simplification of the drawing, the shaft bearing washer B12 and the second wall face W2 are omitted. Also in a case in which the bearing fixing stand B13 is the insulator I3, each of the first stirring blade 131 and the second stirring blade 132 is electrically insulated from the second wall face W2. In other words, also in this case, the reverberation chamber 1 can inhibit a space between each of the first stirring blade 131 and the second stirring blade 132 and the second wall face W2 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, in the example illustrated in FIG. 8, at least one of the housing bearing washer B11, the shaft bearing washer B12, and the plurality of metal spheres may be made of metal, a conductor other than metal, or an insulator.

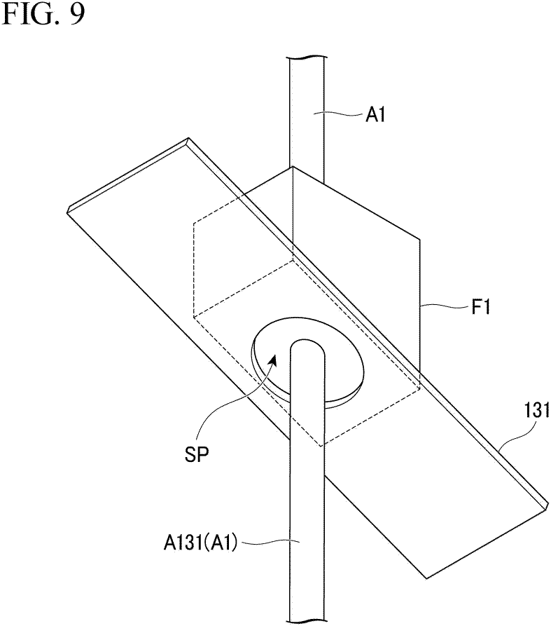

In the electromagnetic stirrer 13A, the holding body H1 includes an insulator 14 that electrically insulates the first stirring blade 131 and the holding body H1 from each other. In other words, the electromagnetic stirrer 13A includes the insulator I4. Here, in the first stirring blade 131, as illustrated in FIG. 9, an opening that separates the first stirring blade 131 and the holding body A1 from each other is formed as a gap SP. In other words, in this case, the holding body A1 is inserted into and passes through this opening and is not directly in contact with the first stirring blade 131. FIG. 9 is a diagram illustrating an example of a gap SP formed in the first stirring blade 131.

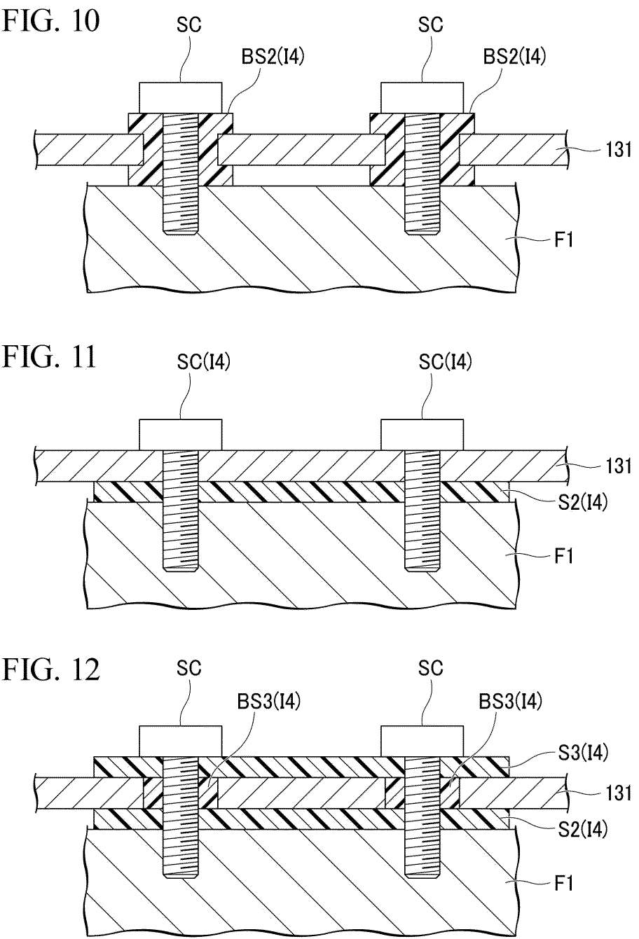

For example, as illustrated in FIG. 10, the insulator I4 configures a plurality of bushes BS2 made of insulators. FIG. 10 is a diagram illustrating an example of an appearance of the first stirring blade 131 fixed to the flange F1. In the first stirring blade 131, a plurality of openings which fixing tools SC such as screws fixing the first stirring blade 131 and the flange F1 are inserted into and pass through are formed. A flange bush made of an insulator buried in a space between the fixing tool SC and the flange F1 inside an opening is inserted into each of the plurality of such openings as a bush BS2. In addition, the bush BS2 that is a flange bush is buried between the first stirring blade 131 and the flange F1 and between the fixing tool SC and the first stirring blade 131 using a flange part of the flange bush also outside the opening which the fixing tool SC is inserted in and passes through. For this reason, also in a case in which the first stirring blade 131 and the flange F1 are fixed using the fixing tool SC, the fixing tool SC is not in contact with the first stirring blade 131. In other words, also in this case, the fixing tool SC is electrically insulated from the first stirring blade 131. In addition, also in a case in which the first stirring blade 131 and the flange F1 are fixed using the fixing tool SC, the flange F1 is not in contact with the first stirring blade 131. In other words, also in this case, the flange F1 is electrically insulated from the first stirring blade 131. In other words, by including the insulator 14 in the electromagnetic stirrer 13A, the first stirring blade 131 is electrically insulated from the holding body H1. Thus, in the example illustrated in FIG. 10, the first stirring blade 131 is electrically insulated from the holding body H1.

In a case in which the first stirring blade 131 and the holding body H1 are electrically insulated from each other, the reverberation chamber 1 can inhibit all spaces between the first stirring blade 131 and the first wall face W1, between the first stirring blade 131 and the second wall face W2, and between the first stirring blade 131 and the second stirring blade 132 from functioning as capacitors. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

In addition, as illustrated in FIG. 11, the insulator I4 may configure each of a plurality of fixing tools SC fixing the first stirring blade 131 and the flange F1 and the spacer S2 disposed between the first stirring blade 131 and the flange F1. FIG. 11 is a diagram illustrating another example of the appearance of the first stirring blade 131 fixed to the flange F1. Also in a case in which the fixing tool SC and the spacer S2 are configured using the insulator I4, the first stirring blade 131 is electrically insulated from the holding body H1. Thus, also in this case, the reverberation chamber 1 can inhibit each of spaces between the first stirring blade 131 and the first wall face W1, between the first stirring blade 131 and the second wall face W2, and between the first stirring blade 131 and the second stirring blade 132 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

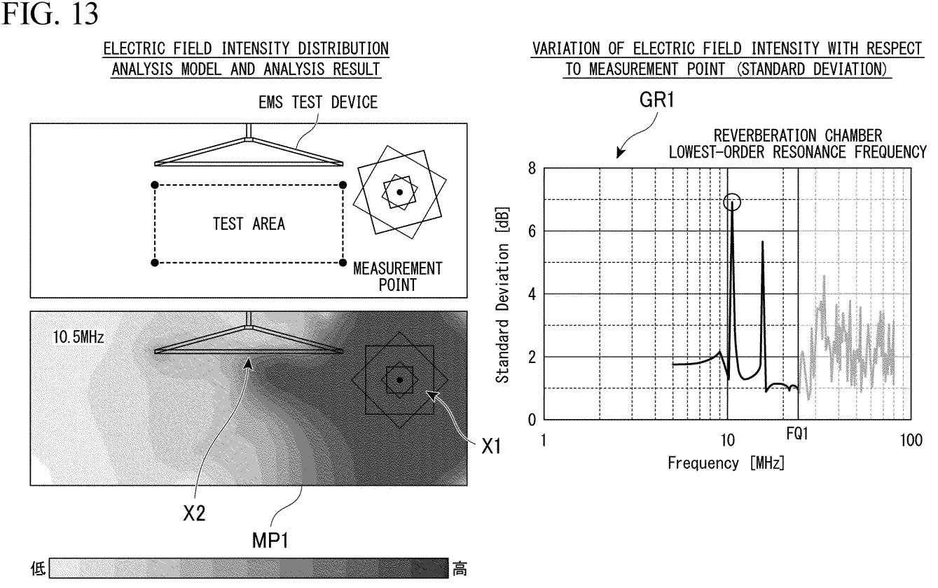

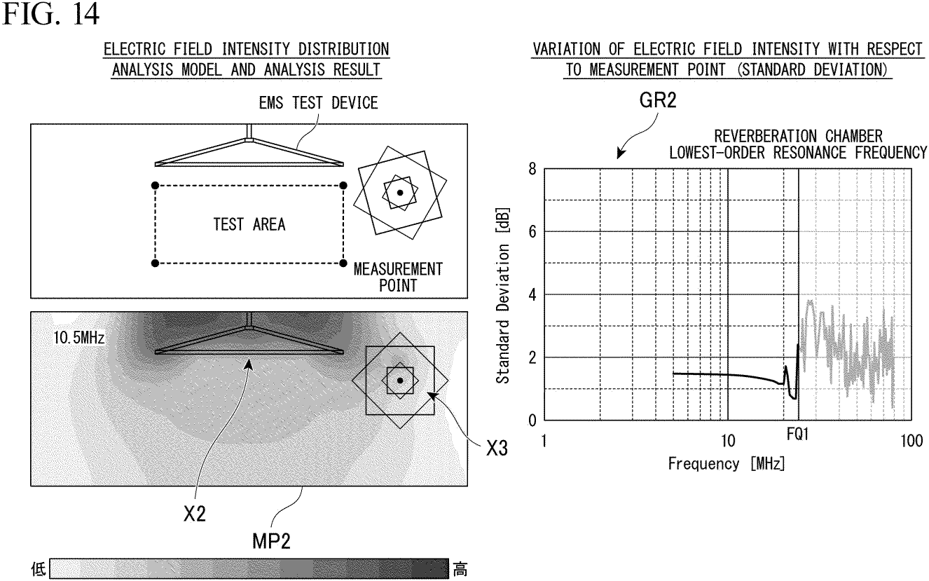

In addition, as illustrated in FIG. 12, the insulator I4 may configure each of a bush BS3 buried between the fixing tool SC and the first stirring blade 131 inside openings which the spacer S2 and the plurality of fixing tools SC made of metal are inserted into and pass through and a spacer S3 between the first stirring blade 131 and the fixing tool SC (for example, a spacer between a screw head of the fixing tool SC that is a screw and the first stirring blade 131) outside the opening. FIG. 12 is a diagram illustrating further another example of the appearance of the first stirring blade 131 fixed to the flange F1. Also in this case, the first stirring blade 131 is electrically insulated from the holding body H1. Thus, also in this case, the reverberation chamber 1 can inhibit each of spaces between the first stirring blade 131 and the first wall face W1, between the first stirring blade 131 and the second wall face W2, and between the first stirring blade 131 and the second stirring blade 132 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. At least one of the plurality of fixing tools SC may be conductors other than metal.

In addition, in the electromagnetic stirrer 13A, the holding body H2 includes an insulator 15 that electrically insulates the second stirring blade 132 and the holding body H2. In other words, the electromagnetic stirrer 13A includes the insulator I5. Here, in the second stirring blade 132, an opening separating the second stirring blade 132 and the holding body A132 from each other is formed as a gap SP2. In other words, in this case, the holding body A1 is inserted into and passes through this opening and is not in direct contact with the second stirring blade 132. The configuration of the gap SP2 formed in the second stirring blade 132 is a configuration similar to that of the gap SP formed in the first stirring blade 131 illustrated in FIG. 9. For this reason, detailed description of the configuration of the gap SP2 will be omitted. In addition, the configuration of the insulator I5 electrically insulating the second stirring blade 132 and the holding body H2 from each other is a configuration similar to the configuration of the insulator I4 electrically insulating the first stirring blade 131 and the holding body H1 from each other. For this reason, detailed description of the configuration of the insulator I5 will be omitted. In a case in which the electromagnetic stirrer 13A includes the insulator I5, the reverberation chamber 1 can inhibit each of spaces between the second stirring blade 132 and the first wall face W1, between the second stirring blade 132 and the second wall face W2, and between the first stirring blade 131 and the second stirring blade 132 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

As above, by including the insulators I1 to I5 in the electromagnetic stirrer 13A, the reverberation chamber 1 can inhibit all the spaces between the first stirring blade 131 and the first wall face W1, between the first stirring blade 131 and the second wall face W2, and between the first stirring blade 131 and the second stirring blade 132 from functioning as capacitors. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, in the reverberation chamber 1, the electromagnetic stirrer 13A may be configured not to include at least one of the insulators I1 to I5. In this case, the reverberation chamber 1 can inhibit at least some of spaces between the first stirring blade 131 and the first wall face W1, between the first stirring blade 131 and the second wall face W2, and between the first stirring blade 131 and the second stirring blade 132 from functioning as capacitors. Also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

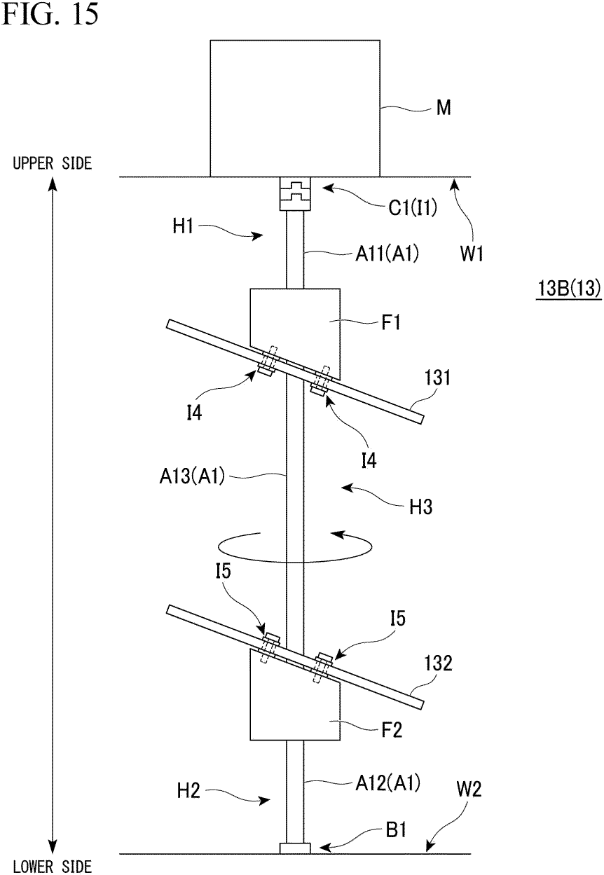

Here, FIG. 13 is a diagram illustrating an electric field intensity inside the reverberation chamber 1 formed in a case in which a conventional electromagnetic stirrer is included in the reverberation chamber 1 in place of the electromagnetic stirrer 13A. Hereinafter, for the convenience of description, a reverberation chamber 1 including a conventional electromagnetic stirrer in place of the electromagnetic stirrer 13A will be referred to as a reverberation chamber 1X in description. FIG. 13 illustrates a case in which a conventional electromagnetic stirrer is disposed in the reverberation chamber IX such that it rotates in a direction orthogonal to the direction of gravity, that is, around a rotation shaft parallel to a horizontal direction as an example.

A graph GR1 illustrated in FIG. 13 is a spectrum representing variations of an electric field intensity for each frequency inside the reverberation chamber 1X. A vertical axis of the graph GR1 represents a standard deviation of the electric field intensity as a value representing variations of the electric field intensity inside the reverberation chamber 1X. On the other hand, a horizontal axis of the graph GR1 represents a frequency of the electric field inside the reverberation chamber 1X. A frequency FQ1 illustrated in the graph GR1 represents an example of the lowest-order resonance frequency. The graph GR1 represents that a variation of the electric field intensity of the inside of the reverberation chamber 1X increases at 10.5 MHz that is a frequency lower than the frequency FQ1. A cause for an increase in the variation of the electric field intensity is the LC resonance circuit described above.

The variation of the electric field intensity inside the reverberation chamber 1X being large at 10.5 MHz is clearly indicated by a distribution chart MP1 illustrated in FIG. 13. The distribution chart MP1 illustrates an example of a distribution of an electric field intensity of which a frequency is 10.5 MHz inside the reverberation chamber 1X. More specifically, the distribution chart MP1 is a contour map representing an electric field intensity at each position inside the reverberation chamber 1X acquired in a case in which the inside of the reverberation chamber 1X is seen in a direction parallel to the rotation shaft of a conventional electromagnetic stirrer. For this reason, in the distribution chart MP1, a graphic symbol X1 representing a position of the conventional electromagnetic stirrer, and a graphic symbol X2 representing a position of an antenna 126 are drawn. The distribution chart MP1 represents that the electric field intensity of the inside of the reverberation chamber 1X becomes stronger as the position becomes closer to the graphic symbol X1 representing the conventional electromagnetic stirrer. In other words, the distribution chart MP1 represents that a distribution of the electric field intensity of the inside of the reverberation chamber 1X is a non-uniform distribution. This is one of evidences indicating that a conventional electromagnetic stirrer functions as an LC resonance circuit.

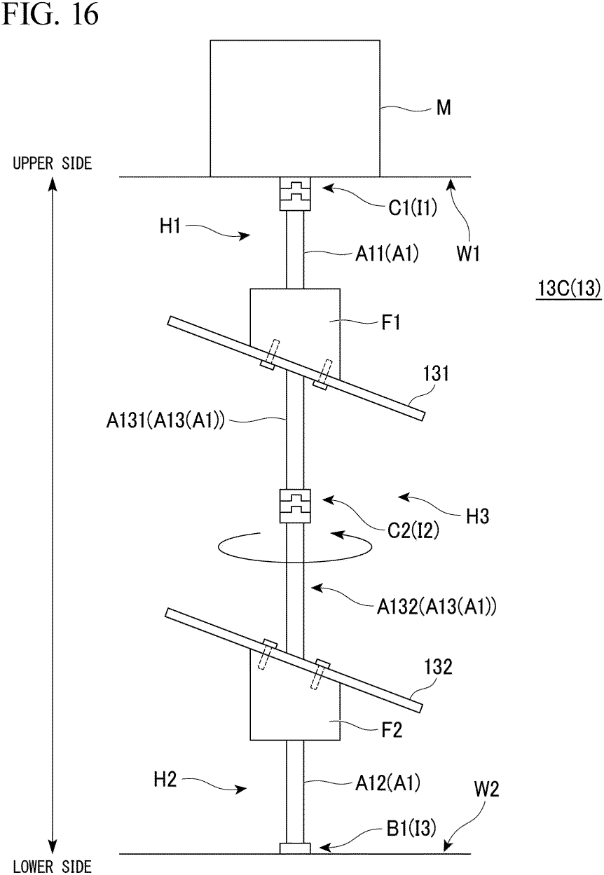

On the other hand, FIG. 14 is a diagram illustrating an electric field intensity of the inside of the reverberation chamber 1. FIG. 14 illustrates a case in which the electromagnetic stirrer 13A is disposed in the reverberation chamber 1 such that it rotates in a direction orthogonal to the direction of gravity, that is, around a rotation shaft parallel to a horizontal direction as an example.

A graph GR2 illustrated in FIG. 14 is a spectrum representing variations of the electric field intensity for each frequency inside the reverberation chamber 1. A vertical axis of the graph GR2 represents a standard deviation of the electric field intensity as a value representing a variation of the electric field intensity of the inside of the reverberation chamber 1. On the other hand, a horizontal axis of the graph GR2 represents a frequency of the electric field of the inside of the reverberation chamber 1. The graph GR2 indicates that an increase in the variation of the electric field intensity of the inside of the reverberation chamber 1 does not occur at a frequency lower than a frequency FQ1. This reflects that each of a combination of the electromagnetic stirrer 13A and the cavity resonator 11 and the electromagnetic stirrer 13A is inhibited from functioning as a capacitor inside the reverberation chamber 1.

A variation of the electric field intensity at 10.5 MHz inside the reverberation chamber 1 being not large is clearly indicated in a distribution chart MP2 illustrated in FIG. 14. The distribution chart MP2 is a distribution of the inside of the reverberation chamber 1 and is an example of a distribution of an electric field intensity of which a frequency is 10.5 MHz. More specifically, the distribution chart MP2 is a contour map representing an electric field intensity at each position inside the reverberation chamber 1 acquired in a case in which the inside of the reverberation chamber 1 is seen in a direction parallel to the rotation shaft of the electromagnetic stirrer 13A. For this reason, in the distribution chart MP2, a graphic symbol X3 representing a position of the electromagnetic stirrer 13A, and a graphic symbol X2 representing a position of an antenna 126 are drawn. The distribution chart MP2 represents that the electric field intensity of the inside of the reverberation chamber 1 becomes almost uniform around the graphic symbol X2 representing the antenna 126. In other words, the distribution chart MP2 represents that the distribution of the electric field intensity of the inside of the reverberation chamber 1 is an almost uniform distribution.

As above, the reverberation chamber 1 can inhibit at least one of spaces between the first stirring blade 131 and the first wall face W1, between the first stirring blade 131 and the second wall face W2, between the second stirring blade 132 and the first wall face W1, between the second stirring blade 132 and the second wall face W2, and between the first stirring blade 131 and the second stirring blade 132 from functioning as a capacitor. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

### Configuration Example 2 of Electromagnetic Stirrer

Hereinafter, Configuration example 2 of the electromagnetic stirrer 13 will be described with reference to FIG. 15. FIG. 15 is a diagram illustrating Configuration example 2 of the electromagnetic stirrer 13. Hereinafter, for the convenience of description, the electromagnetic stirrer 13 illustrated in FIG. 15 will be referred to as an electromagnetic stirrer 13B in description. An arrow illustrated in FIG. 15 represents upward/downward directions in FIG. 15. The upward direction represented by this arrow represents a direction opposite to the direction of gravity. In addition, the downward direction represented by this arrow represents the direction of gravity.

The electromagnetic stirrer 13B illustrated in FIG. 15 is a modified example of the electromagnetic stirrer 13A. The electromagnetic stirrer 13B does not include the coupling C2 including the insulator 12, and a part A13 is configured as a single member. In the electromagnetic stirrer 13B, a bearing B1 is a thrust bearing made of metal that does not include the insulator I3. However, similar to the electromagnetic stirrer 13A, the electromagnetic stirrer 13B includes an insulator I1, an insulator I4, and an insulator 15. In the example illustrated in FIG. 15, at least a part of a coupling C1 is configured using the insulator I1. In this example, a holding body H1 of the electromagnetic stirrer 13B includes the insulator I4 that electrically insulates a first stirring blade 131 and the holding body H1 from each other. In addition, in this example, a holding body H2 of the electromagnetic stirrer 13B includes the insulator I5 that electrically insulates a second stirring blade 132 and a holding body H2 from each other. Also in this case, in the reverberation chamber 1, each of the first stirring blade 131 and the second stirring blade 132 is electrically insulated from a first wall face W1, each of the first stirring blade 131 and the second stirring blade 132 is electrically insulated from a second wall face W2, and the first stirring blade 131 and the second stirring blade 132 are electrically insulated from each other. As a result, also in this case, the reverberation chamber 1 can inhibit all spaces between the first stirring blade 131 and the first wall face W1, between the first stirring blade 131 and the second wall face W2, between the second stirring blade 132 and the first wall face W1, between the second stirring blade 132 and the second wall face W2, and the first stirring blade 131 and the second stirring blade 132 from functioning as capacitors. Thus, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In the electromagnetic stirrer 13B, at least a part of a bearing B1 may be configured using the insulator 13. In addition, the electromagnetic stirrer 13B may be configured to include at least one of the insulator I1, the insulator I4, and the insulator 15. Furthermore, the electromagnetic stirrer 13B may be configured to include one or both of the insulator I2 and the insulator I3 in place of at least one of the insulator I1, the insulator I4, and the insulator I5. In such a case, the reverberation chamber 1 can inhibit some of spaces between the first stirring blade 131 and the first wall face W1, between the first stirring blade 131 and the second wall face W2, between the second stirring blade 132 and the first wall face W1, between the second stirring blade 132 and the second wall face W2, and the first stirring blade 131 and the second stirring blade 132 from functioning as capacitors.

### Configuration Example 3 of Electromagnetic Stirrer

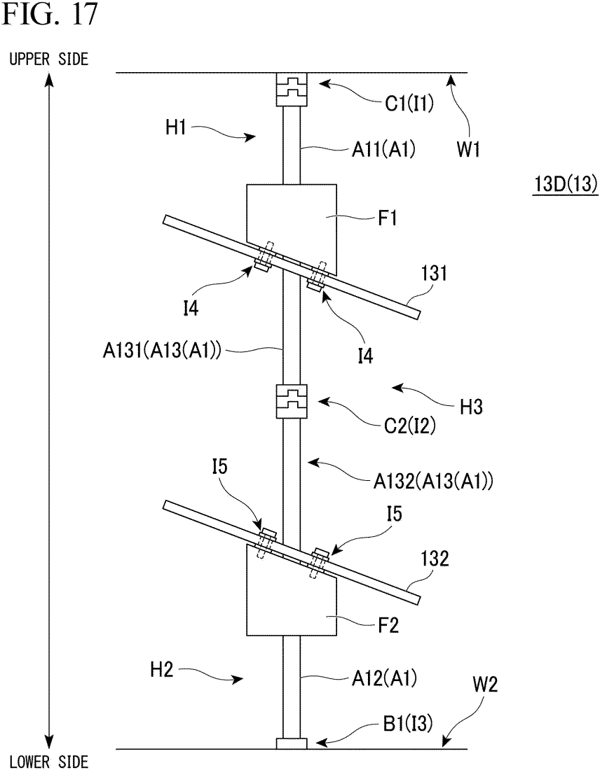

Hereinafter, Configuration example 3 of the electromagnetic stirrer 13 will be described with reference to FIG. 16. FIG. 16 is a diagram illustrating Configuration example 3 of the electromagnetic stirrer 13. Hereinafter, for the convenience of description, the electromagnetic stirrer 13 illustrated in FIG. 16 will be referred to as an electromagnetic stirrer 13C in description. An arrow illustrated in FIG. 16 represents upward/downward directions in FIG. 16. The upward direction represented by this arrow represents a direction opposite to the direction of gravity. In addition, the downward direction represented by this arrow represents the direction of gravity.

The electromagnetic stirrer 13C illustrated in FIG. 16 is a modified example of the electromagnetic stirrer 13A. The electromagnetic stirrer 13C does not include the insulator I4 and the insulator I5. However, similar to the electromagnetic stirrer 13A, the electromagnetic stirrer 13C includes the insulator I1 to the insulator I3. In the example illustrated in FIG. 16, at least a part of a coupling C1 is configured using the insulator I1. In addition, in this example, at least a part of a coupling C2 is configured using the insulator 12. In this example, at least a part of a bearing B1 is configured using the insulator I3. Also in this case, in the reverberation chamber 1, each of the first stirring blade 131 and the second stirring blade 132 is electrically insulated from a first wall face W1, each of the first stirring blade 131 and the second stirring blade 132 is electrically insulated from a second wall face W2, and the first stirring blade 131 and the second stirring blade 132 are electrically insulated from each other. As a result, also in this case, the reverberation chamber 1 can inhibit all spaces between the first stirring blade 131 and the first wall face W1, between the first stirring blade 131 and the second wall face W2, between the second stirring blade 132 and the first wall face W1, between the second stirring blade 132 and the second wall face W2, and the first stirring blade 131 and the second stirring blade 132 from functioning as capacitors. Thus, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, the electromagnetic stirrer 13B may be configured to any one of the insulator I4 and the insulator I5 in addition to the insulator I1 to the insulator I3. Furthermore, the electromagnetic stirrer 13B may be configured to include one or both of the insulator I4 and the insulator 15 in place of some or all of the insulator I1 to the insulator 13.

### Configuration Example 4 of Electromagnetic Stirrer

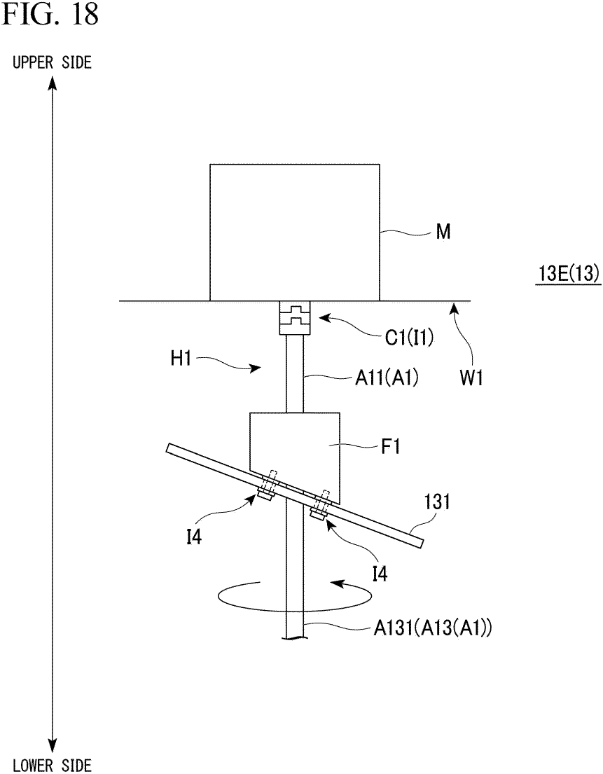

Hereinafter, Configuration example 4 of the electromagnetic stirrer 13 will be described with reference to FIG. 17. FIG. 17 is a diagram illustrating Configuration example 4 of the electromagnetic stirrer 13. Hereinafter, for the convenience of description, the electromagnetic stirrer 13 illustrated in FIG. 17 will be referred to as an electromagnetic stirrer 13D in description. An arrow illustrated in FIG. 17 represents upward/downward directions in FIG. 17. The upward direction represented by this arrow represents a direction opposite to the direction of gravity. In addition, the downward direction represented by this arrow represents the direction of gravity.

The electromagnetic stirrer 13D illustrated in FIG. 17 is a modified example of the electromagnetic stirrer 13A. The electromagnetic stirrer 13D does not include a motor M and includes a direct acting actuator, which is not illustrated, vibrating the electromagnetic stirrer 13D in a first direction. For example, this direct acting actuator is disposed in at least one of a flange F1 and a flange F2. On the other hand, similar to the electromagnetic stirrer 13A, the electromagnetic stirrer 13D includes an insulator I1 to an insulator I5. In the example illustrated in FIG. 17, at least a part of a coupling C1 is configured using the insulator I1. In addition, in this example, at least a part of a coupling C2 is configured using the insulator I2. In this example, at least a part of a bearing B1 is configured using the insulator I3. In this example, a holding body H1 of the electromagnetic stirrer 13D includes the insulator I4 that electrically insulates a first stirring blade 131 and the holding body H1 from each other. In addition, in this example, a holding body H2 of the electromagnetic stirrer 13D includes the insulator I5 that electrically insulates a second stirring blade 132 and a holding body H2 from each other. Thus, also in this case, in the reverberation chamber 1, each of the first stirring blade 131 and the second stirring blade 132 is electrically insulated from a first wall face W1, each of the first stirring blade 131 and the second stirring blade 132 is electrically insulated from a second wall face W2, and the first stirring blade 131 and the second stirring blade 132 are electrically insulated from each other. As a result, also in this case, the reverberation chamber 1 can inhibit all spaces between the first stirring blade 131 and the first wall face W1, between the first stirring blade 131 and the second wall face W2, between the second stirring blade 132 and the first wall face W1, between the second stirring blade 132 and the second wall face W2, and between the first stirring blade 131 and the second stirring blade 132 from functioning as capacitors. Thus, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, the electromagnetic stirrer 13D may be configured to include at least one of the insulator 11 to the insulator 15. In such a case, the reverberation chamber 1 can inhibit some of spaces between the first stirring blade 131 and the first wall face W1, between the first stirring blade 131 and the second wall face W2, between the second stirring blade 132 and the first wall face W1, between the second stirring blade 132 and the second wall face W2, and the first stirring blade 131 and the second stirring blade 132 from functioning as capacitors.

### Configuration Example 5 of Electromagnetic Stirrer

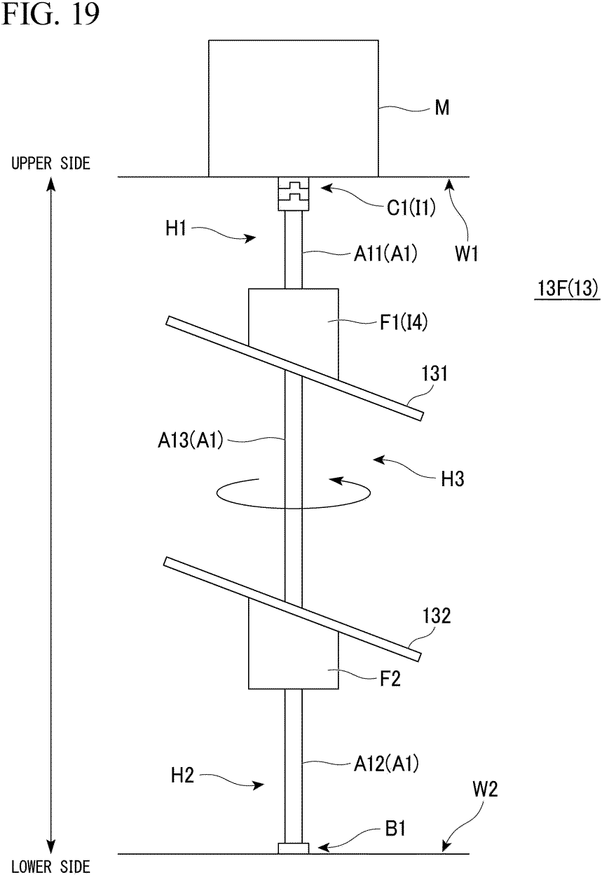

Hereinafter, Configuration example 5 of the electromagnetic stirrer 13 will be described with reference to FIG. 18. FIG. 18 is a diagram illustrating Configuration example 5 of the electromagnetic stirrer 13. Hereinafter, for the convenience of description, the electromagnetic stirrer 13 illustrated in FIG. 18 will be referred to as an electromagnetic stirrer 13E in description. An arrow illustrated in FIG. 18 represents upward/downward directions in FIG. 18. The upward direction represented by this arrow represents a direction opposite to the direction of gravity. In addition, the downward direction represented by this arrow represents the direction of gravity.

The electromagnetic stirrer 13E illustrated in FIG. 18 is a modified example of the electromagnetic stirrer 13A. A holding body A1 of the electromagnetic stirrer 13E includes not a part A12 and a holding body A132 of a part A13 but a part A11 and a holding body A131 of a part A13. The electromagnetic stirrer 13E illustrated in FIG. 18 includes not a coupling C2, a second stirring blade 132, a flange F2, and a bearing B1 but a first stirring blade 131. In addition, the holding body A1 may be configured not to include a holding body A131.

For this reason, the electromagnetic stirrer 13E is connected to a first wall face W1 and is not connected to a second wall face W2. Similar to the electromagnetic stirrer 13A, the electromagnetic stirrer 13E includes an insulator I1 and an insulator I4. In the example illustrated in FIG. 18, at least a part of a coupling C1 is configured using the insulator I1. In this example, a holding body H1 of the electromagnetic stirrer 13D includes the insulator I4 that electrically insulates a first stirring blade 131 and the holding body H1 from each other. In this case, in the reverberation chamber 1, the first stirring blade 131 and the first wall face W1 are electrically insulated from each other. In addition, in this case, naturally, the reverberation chamber 1 is electrically insulated from the first stirring blade 131 and the second wall face W2. As a result, also in this case, the reverberation chamber 1 can inhibit each of spaces between the first stirring blade 131 and the first wall face W1 and between the first stirring blade 131 and the second wall face W2 from functioning as a capacitor. Thus, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, the electromagnetic stirrer 13E may be configured not to include any one of the insulator I1 and the insulator I4.

### Configuration Example 6 of Electromagnetic Stirrer

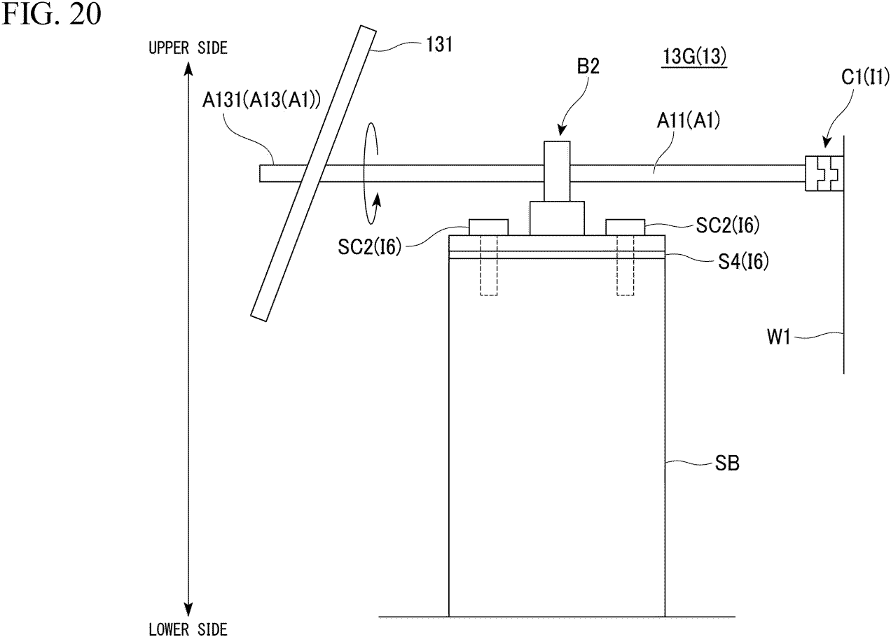

Hereinafter, Configuration example 6 of the electromagnetic stirrer 13 will be described with reference to FIG. 19. FIG. 19 is a diagram illustrating Configuration example 6 of the electromagnetic stirrer 13. Hereinafter, for the convenience of description, the electromagnetic stirrer 13 illustrated in FIG. 19 will be referred to as an electromagnetic stirrer 13F in description. An arrow illustrated in FIG. 19 represents upward/downward directions in FIG. 19. The upward direction represented by this arrow represents a direction opposite to the direction of gravity. In addition, the downward direction represented by this arrow represents the direction of gravity.

The electromagnetic stirrer 13F illustrated in FIG. 19 is a modified example of the electromagnetic stirrer 13A. The electromagnetic stirrer 13F does not include the coupling C2 including the insulator I2, and a part A13 is configured as a single member. In the electromagnetic stirrer 13F, each of a holding body A1, a flange F1, and a flange F2 is made of an insulator. In other words, the electromagnetic stirrer 13F includes the holding body A1 made of an insulator, the flange F1 made of an insulator, and the flange F2 made of an insulator as an insulator I4 and an insulator I5. In addition to this, the electromagnetic stirrer 13F includes an insulator I1 and an insulator I3. Also in this case, in the reverberation chamber 1, each of the first stirring blade 131 and the second stirring blade 132 is electrically insulated from a first wall face W1, each of the first stirring blade 131 and the second stirring blade 132 is electrically insulated from a second wall face W2, and the first stirring blade 131 and the second stirring blade 132 are electrically insulated from each other. As a result, also in this case, the reverberation chamber 1 can inhibit all spaces between the first stirring blade 131 and the first wall face W1, between the first stirring blade 131 and the second wall face W2, between the second stirring blade 132 and the first wall face W1, between the second stirring blade 132 and the second wall face W2, and the first stirring blade 131 and the second stirring blade 132 from functioning as capacitors. Thus, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy. In addition, the electromagnetic stirrer 13F may be configured to include a coupling C2. Furthermore, in the electromagnetic stirrer 13F, at least one of the holding body A1, the flange F1, and the flange F2 may be made of metal or a conductor other than metal.

### Configuration Example 7 of Electromagnetic Stirrer

Hereinafter, Configuration example 7 of the electromagnetic stirrer 13 will be described with reference to FIG. 20. FIG. 20 is a diagram illustrating Configuration example 7 of the electromagnetic stirrer 13. Hereinafter, for the convenience of description, the electromagnetic stirrer 13 illustrated in FIG. 20 will be referred to as an electromagnetic stirrer 13G in description. An arrow illustrated in FIG. 20 represents upward/downward directions in FIG. 20. The upward direction represented by this arrow represents a direction opposite to the direction of gravity. In addition, the downward direction represented by this arrow represents the direction of gravity.

The electromagnetic stirrer 13G illustrated in FIG. 20 is a modified example of the electromagnetic stirrer 13E. In the example illustrated in FIG. 20, a first wall face W1 is one of side wall faces inside a cavity resonator 11 in place of a ceiling face inside the cavity resonator 11. For this reason, the first direction described above is a direction intersecting with a side wall face used as the first wall face W1 among wall faces of the inside of the cavity resonator 11. In the example illustrated in FIG. 20, the first direction is a direction orthogonal to this first wall face W1, that is, a direction orthogonal to the direction of gravity. For this reason, a holding body A1 of the electromagnetic stirrer 13G is disposed on the first wall face W1 such that a rotation shaft of the electromagnetic stirrer 13G is orthogonal to the direction of gravity. In FIG. 20, for simplification of the drawing, a motor M and a flange F1 are omitted.

In this example illustrated in FIG. 20, in accordance with weight of a first stirring blade 131, a moment for rotating a part A11 in the direction of gravity with a position near the coupling C1 as its center is added. Thus, in this example, the reverberation chamber 1 further includes a support body SB that supports the part A11 of the holding body A1. In addition, the support body SB may be configured to support a holding body A131 of the holding body A1 instead of the configuration for supporting the part A11 of the holding body A1.

The support body SB includes a bearing B2, a first support body SB1 supporting the bearing B2, a second support body SB2 supporting the first support body SB1, a spacer S4 disposed between the first support body SB1 and the second support body SB2, and a plurality of fixing tools SC2 fixing the first support body SB1 and the second support body SB2.

The bearing B2 is a bearing made of metal which the holding body A1 is inserted into and passes through and receives the rotating holding body A1. In addition, the bearing B2 may be made of a conductor other than metal in place of the metal.

The first support body SB1 is a member made of metal that supports the bearing B2. In addition, the first support body SB1 may be made of a conductor other than metal in place of the metal.

The second support body SB2 is a member made of metal that supports the first support body SB1. In addition, the second support body SB2 may be made of a conductor other than metal in place of the metal.

The spacer S4 is a spacer made of an insulator and is configured using an insulator I6.

For example, the fixing tool SC2 is a screw made of an insulator and is configured using the insulator 16.

In this way, the reverberation chamber 1 includes the insulator 16 in addition to an insulator I1 included in the coupling C1 and an insulator I4 that electrically insulates the first stirring blade 131 and the holding body H1 from each other. As illustrated in FIG. 20, the insulator I6 electrically insulates the first support body SB1 and the second support body SB2 from each other. In other words, the insulator I6 electrically insulates the electromagnetic stirrer 13A and a floor face of the reverberation chamber 1 on which the second support body SB2 is fixed from each other. Thus, also in a case in which the support body SB supporting the holding body A1 of the electromagnetic stirrer 13A is included, the reverberation chamber 1 can inhibit a space between the first stirring blade 131 and the first wall face W1 from functioning as a capacitor by including the insulator 16. As a result, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

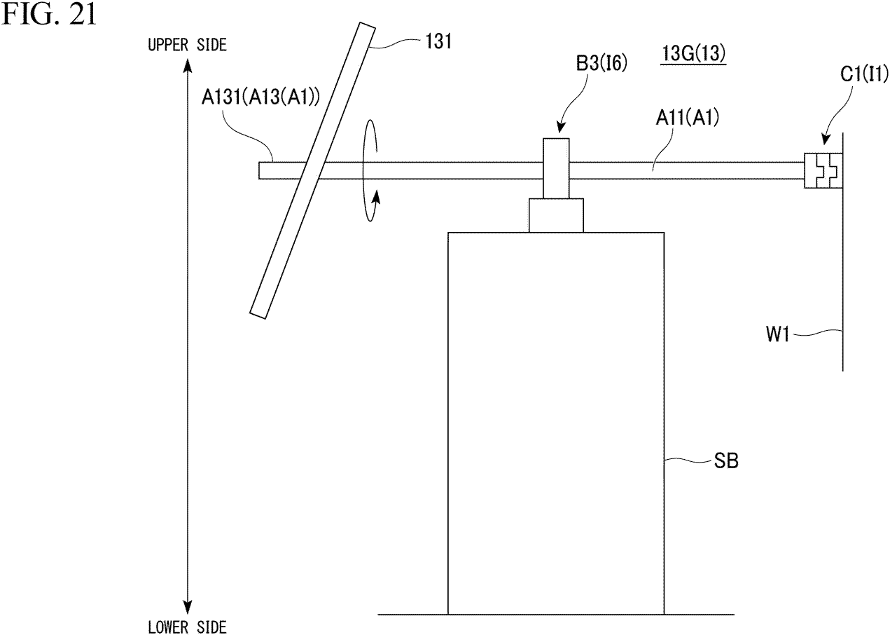

In addition, as illustrated in FIG. 21, by including a bearing B3 in place of the bearing B2, the support body SB may be configured not to include the spacer S4, and the first support body SB1 and the second support body SB2 may be integrally configured. FIG. 21 is a diagram illustrating Modified example 1 of the configuration of the support body SB illustrated in FIG. 20. The bearing B3 is a bearing of which a part or the entirety is configured using the insulator I6. For example, the entire bearing B3 may be configured using the insulator I6, a holder may be configured using the insulator I6, or another part that can electrically insulate the holding body A1 and the support body SB from each other may be configured using the insulator 16. Also in this case, the reverberation chamber 1 can inhibit a space between the first stirring blade 131 and the first wall face W1 from functioning as a capacitor. As a result, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

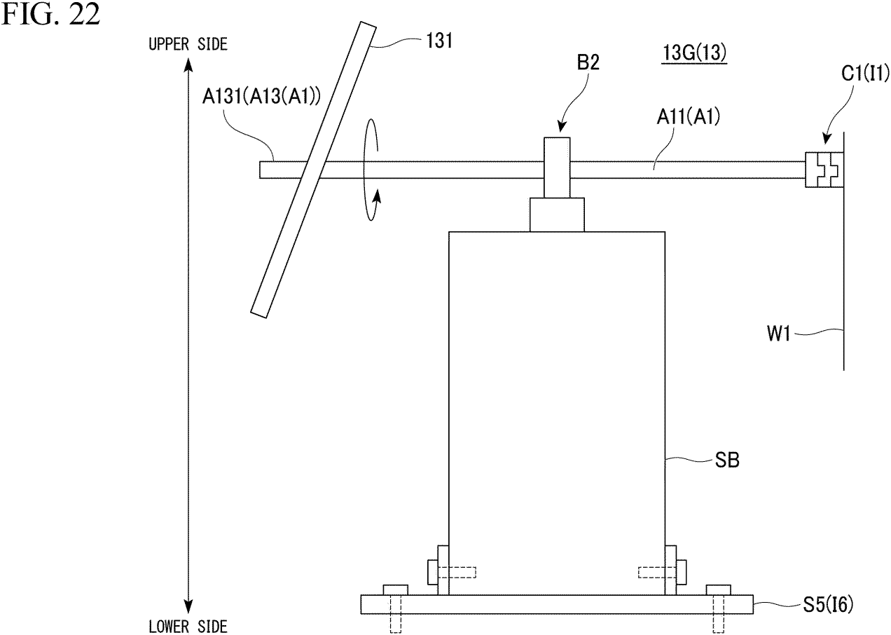

In addition, as illustrated in FIG. 22, the support body SB may include not the spacer S4 but a spacer S5, and the first support body SB1 and the second support body SB2 may be integrally configured. FIG. 22 is a diagram illustrating Modified example 2 of the configuration of the support body SB illustrated in FIG. 20. The spacer S5 is a spacer configured using the insulator 16 and is disposed between the second support body SB2 and the floor face of the reverberation chamber 1. The second support body SB2 is fixed to the spacer S5 using a fixing tool such as a screw. The spacer S5 is fixed to the floor face using a fixing tool such as a screw. Also in this case, the reverberation chamber 1 can inhibit a space between the first stirring blade 131 and the first wall face W1 from functioning as a capacitor. As a result, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

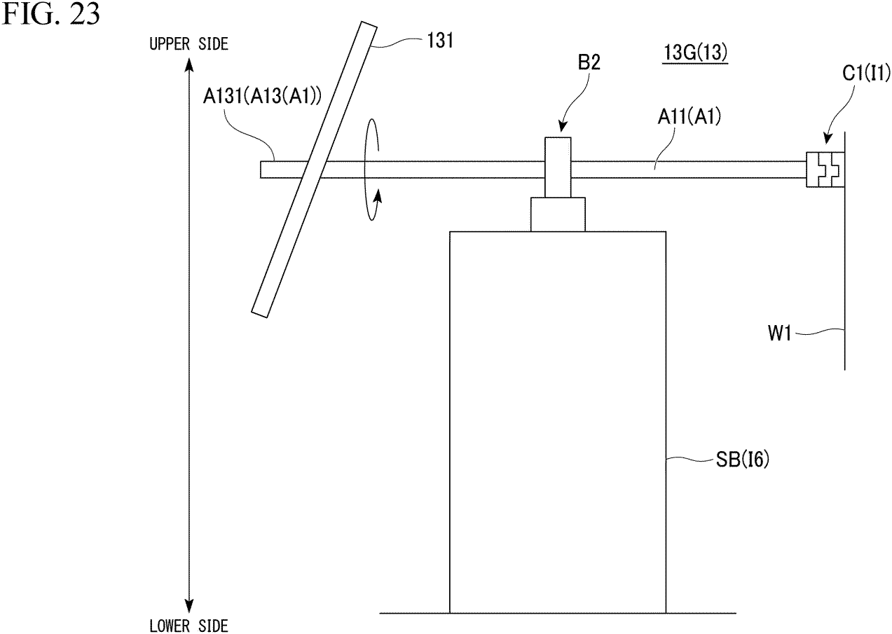

In addition, as illustrated in FIG. 23, the support body SB may not include the spacer S4, each of the first support body SB1 and the second support body SB2 may be configured using the insulator 16, and the first support body SB1 and the second support body SB2 may be integrally configured. FIG. 23 is a diagram illustrating Modified example 3 of the configuration of the support body SB illustrated in FIG. 20. Also in this case, the reverberation chamber 1 can inhibit a space between the first stirring blade 131 and the first wall face W1 from functioning as a capacitor. As a result, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

### Configuration Example 8 of Electromagnetic Stirrer

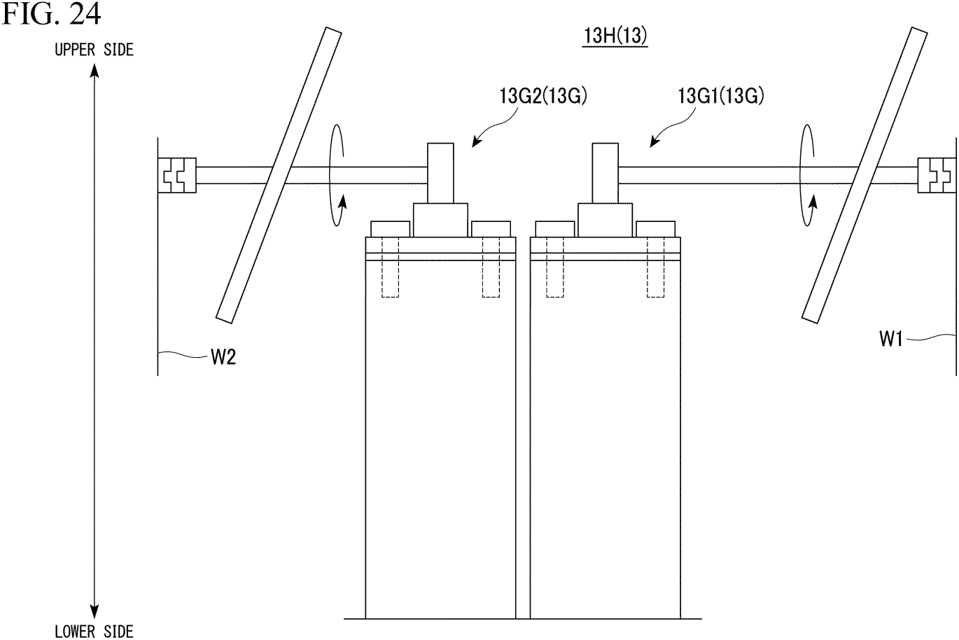

Hereinafter, Configuration example 8 of the electromagnetic stirrer 13 will be described with reference to FIG. 24. FIG. 24 is a diagram illustrating Configuration example 8 of the electromagnetic stirrer 13. Hereinafter, for the convenience of description, the electromagnetic stirrer 13 illustrated in FIG. 24 will be referred to as an electromagnetic stirrer 13H in description. An arrow illustrated in FIG. 24 represents upward/downward directions in FIG. 24. The upward direction represented by this arrow represents a direction opposite to the direction of gravity. In addition, the downward direction represented by this arrow represents the direction of gravity.

The electromagnetic stirrer 13H illustrated in FIG. 24 includes two electromagnetic stirrers 13G illustrated in FIG. 20. Hereinafter, for the convenience of description, one of these two electromagnetic stirrers 13G will be referred to as an electromagnetic stirrer 13G1, and the other of these two electromagnetic stirrers 13G will be referred to as an electromagnetic stirrer 13G2 in description.

In the electromagnetic stirrer 13H illustrated in FIG. 24, a holding body A1 of the electromagnetic stirrer 13G1 is disposed on a first wall face W1 through a coupling C1. On the other hand, in this electromagnetic stirrer 13H, a holding body A1 of the electromagnetic stirrer 13G2 is disposed on a second wall face W2 through the coupling C1. Here, in the example illustrated in FIG. 24, the second wall face W2 is a side wall face facing the first wall face W1 among wall faces of the inside of the reverberation chamber 1. In the example illustrated in FIG. 24, a first stirring blade 131 of the electromagnetic stirrer 13G1 can be perceived as a first stirring blade 131 of the electromagnetic stirrer 13H, and a first stirring blade 131 of the electromagnetic stirrer 13G2 can be perceived as a second stirring blade 132 of the electromagnetic stirrer 13H. In the case of such perception, the reverberation chamber 1 can inhibit all spaces between the first stirring blade 131 of the electromagnetic stirrer 13H and the first wall face W1, between the first stirring blade 131 of the electromagnetic stirrer 13H and the second wall face W2, between the second stirring blade 132 of the electromagnetic stirrer 13H and the first wall face W1,between the second stirring blade 132 of the electromagnetic stirrer 13H and the second wall face W2, and between the first stirring blade 131 of the electromagnetic stirrer 13H and the second stirring blade 132 of the electromagnetic stirrer 13H from functioning as capacitors. As a result, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

### Configuration Example 9 of Electromagnetic Stirrer

Hereinafter, Configuration example 9 of the electromagnetic stirrer 13 will be described with reference to FIG. 25. FIG. 25 is a diagram illustrating Configuration example 9 of the electromagnetic stirrer 13. Hereinafter, for the convenience of description, the electromagnetic stirrer 13 illustrated in FIG. 25 will be referred to as an electromagnetic stirrer 13Iin description. An arrow illustrated in FIG. 25 represents upward/downward directions in FIG. 25. The upward direction represented by this arrow represents a direction opposite to the direction of gravity. In addition, the downward direction represented by this arrow represents the direction of gravity.

The electromagnetic stirrer 13I illustrated in FIG. 25 includes a holding body A1 having a rectangular flat plate shape. In the example illustrated in FIG. 25, a floor face of the cavity resonator 11 is set as a first wall face W1, a direction opposite to the direction of gravity is set as a first direction, and the holding body A1 is slidably placed on the first wall face W1 such that it extends in the first direction. On the surface of this holding body A1, a metal plate of an undulating shape such as a triangular wave is disposed as a first stirring blade 131. In each of the holding body A1 and the first stirring blade 131, an opening formed to pass through from the first stirring blade 131 to the holding body A1 is formed. A part of a support body SB3 supporting the holding body A1 not to fall is inserted into and passes through this opening. For example, the support body SB3 is composed of a first support body SB31 and a second support body SB32. The first support body SB31 is a member that is fixed to the first wall face W1 and extends in the first direction. The second support body SB2 is connected to the first support body SB1, extends in a second direction that is orthogonal to the first direction, and is fixed to a side wall face on a second-direction side among wall faces of the inside of the cavity resonator 11. In the reverberation chamber 1, the holding body A1 vibrates back and forth in the second direction along the second support body SB2. Such vibration is realized using a direct acting actuator or the like that is not illustrated. The support body SB3 is configured using an insulator I7 that insulates the holding body A1 and the first wall face W1 from each other. In other words, the reverberation chamber 1 includes the insulator I7.

In a case in which the electromagnetic stirrer 13I has such a configuration, the holding body A1 is electrically insulated from the support body SB3. As a result, also in this case, the reverberation chamber 1 can inhibit each of spaces between the first stirring blade 131 and the first wall face W1 and between the first stirring blade 131 and the support body SB3 from functioning as a capacitor. In other words, also in this case, the reverberation chamber 1 can inhibit an occurrence of a resonance phenomenon of an electric field of a frequency lower than the lowest-order resonance frequency among electric fields emitted from the antenna 126 to a device under test, and thus an EMS test having high accuracy can be performed in a wider frequency band with good accuracy.

In a part included in the wall face is present inside the cavity resonator 11 described above, a part in which each electromagnetic stirrer 13 and the cavity resonator 11 are in contact with each other may be made of an insulator.

The configurations of the electromagnetic stirrers 13 described above may be combined in any way.

The coupling C1 described above may be a bearing.

In addition, the coupling C2 described above may be a bearing.

Furthermore, the bearing B1 described above may be a coupling.

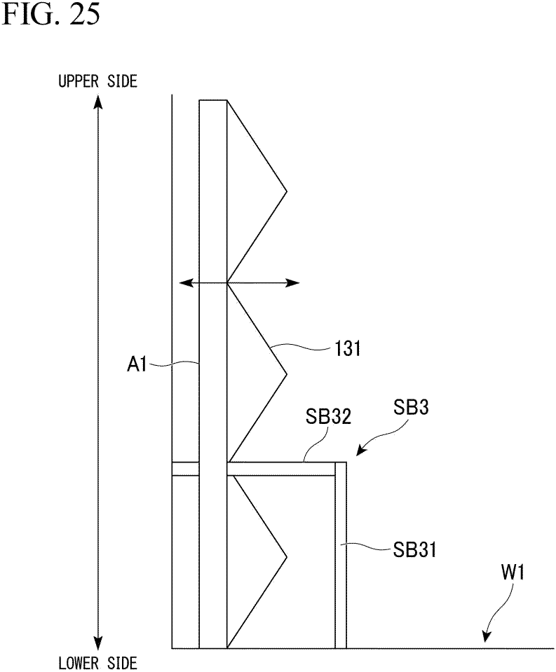

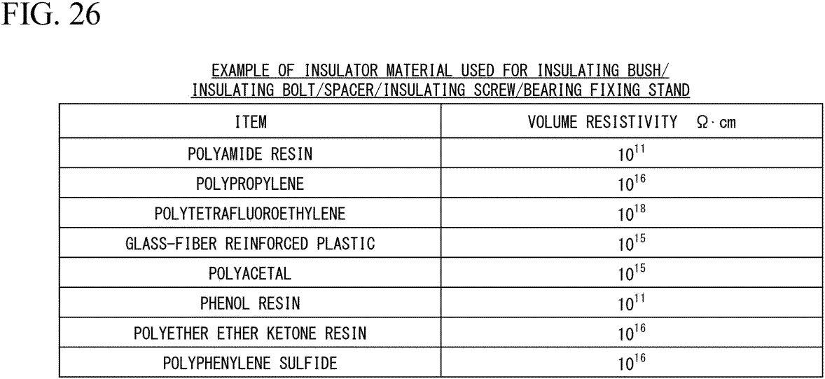

Examples of materials used for a bush made of an insulator such as the bush BS2, a screw (or a bolt) made of an insulator such as the fixing tool SC, a spacer made of an insulator such as the spacer S1, a stand made of an insulator such as the bearing fixing stand B13, and the like, as illustrated in FIG. 26, include a polyamide resin, polypropylene, polytetrafluoroethylene, glass-fiber reinforced plastic, polyacetal, a phenol resin, a polyether ether ketone resin, polyphenylene sulfide, and the like. In other words, it is preferable that this material be a material having electrical resistance of which volume resistivity is at least about 10¹¹ Ω·cm or more. FIG. 26 is a table illustrating a list of materials used for a bush made of an insulator such as the bush BS2, a screw (or a bolt) made of an insulator such as the fixing tool SC, a spacer made of an insulator such as the spacer S1, a stand made of an insulator such as the bearing fixing stand B13, and the like.

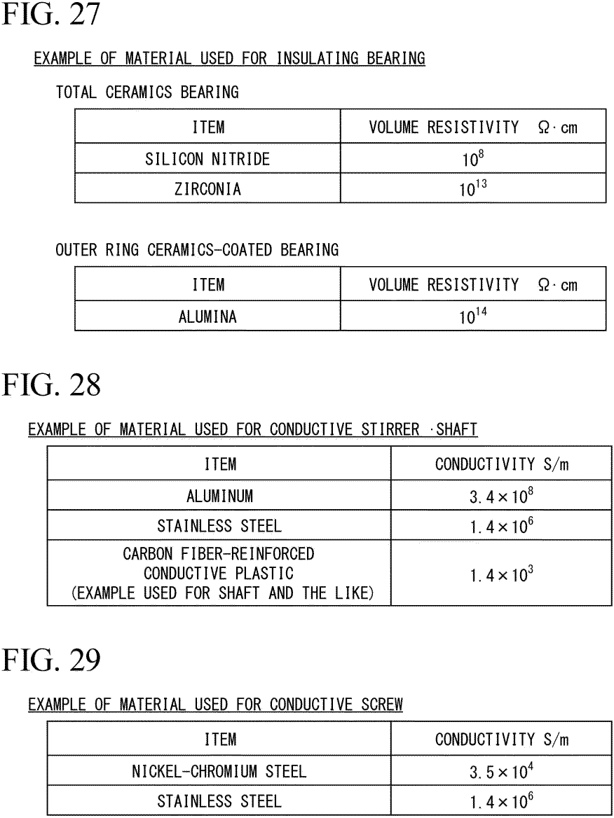

In addition, examples of materials used for a bearing of which entirety is configured using an insulator such as the bearing B1 illustrated in FIG. 6 include, as illustrated in FIG. 27, silicon nitride, zirconia, and the like. In other words, it is preferable that the material is a material having electrical resistance of which volume resistivity is at least about 10⁸ Ω·cm or more. FIG. 27 is a table illustrating a list of materials used in a bearing of which entirety is configured using an insulator such as a bearing B1 illustrated in FIG. 6.

In addition, in FIG. 27, a table representing a list of materials used for coating of the bearing B1 illustrated in FIG. 7 with an insulator is also illustrated. As materials used for coating of the bearing B1 illustrated in FIG. 7 with an insulator, as illustrated in FIG. 27, there are alumina and the like. In other words, it is preferable that this material be a material having electrical resistance of which volume resistivity is at least about 10¹⁴ Ω·cm or more. FIG. 28 is a table illustrating a list of materials used for coating of the bearing B1 illustrated in FIG. 7 with an insulator.

In addition, as described above, materials used for members (for example, the holding body A1, the first stirring blade 131, and the like) other than the cavity resonator 11 and the fixing tool among the members made of metal described above may be metal or a conductor other than metal. For this reason, materials used for this member include, as illustrated in FIG. 28, aluminum, stainless steel (SUS304), carbon fiber-reinforced conductive plastic, and the like. In other words, it is preferable that this material be a material of which conductivity is at least about 10³ S/m or more. FIG. 28 is a table illustrating a list of materials used for members made of conductors.

In addition, the fixing tool (for example, the fixing tool SC made of metal) other than fixing tools clearly described to be made of insulators above may be made of metal or a conductor other than metal. In such a case, examples of materials used for a metal fixing tool or a fixing tool made of a conductor other than metal, as illustrated in FIG. 29, include nickel-chromium steel, stainless steel (SUS304), and the like. In other words, it is preferable that this material be a material of which conductivity is at least about 10⁴ S/m or more. FIG. 29 is a table illustrating a list of materials used for a fixing tool made of metal or conductor other than metal.

As above, a reverberation chamber according to an embodiment (in the example described above, the reverberation chamber 1) is a reverberation chamber including an electromagnetic stirrer (in the example described above, the electromagnetic stirrer 13A to the electromagnetic stirrer 131), in which the electromagnetic stirrer includes: a first stirring blade (in the example described above, the first stirring blade 131); and a holding body (in the example described above, the holding body A1) disposed on a first wall face (in the example described above, the first wall face W1) of the reverberation chamber, extending in a first direction (in the example described above, the direction of gravity, a direction orthogonal to the direction of gravity, a direction opposite to the direction of gravity) intersecting with the first wall face, and configured to hold the first stirring blade, and the first stirring blade is electrically insulated from the first wall face. In accordance with this, the reverberation chamber can perform an EMS test having high accuracy in a wider frequency band.

In addition, in the reverberation chamber, the electromagnetic stirrer may be configured to further include a second stirring blade (in the example described above, the second stirring blade 132) aligned together with the first stirring blade in the first direction and disposed in the holding body.

Furthermore, in the reverberation chamber, the first stirring blade may be configured to be electrically insulated from the second stirring blade.

In addition, there is provided a reverberation chamber including an electromagnetic stirrer, in which, the electromagnetic stirrer includes: a first stirring blade; a second stirring blade; and a holding body disposed on a first wall face of the reverberation chamber, extending in a first direction intersecting with the first wall face, configured to hold the first stirring blade and the second stirring blade to be aligned in the first direction, and the first stirring blade is electrically insulated from the second stirring blade. In accordance with this, the reverberation chamber can perform an EMS test having high accuracy in a wider frequency band.

In addition, in the reverberation chamber, the holding body may be configured to include a first insulator (in the example described above, the insulator I3) electrically insulating the first stirring blade and the second stirring blade from each other.

Furthermore, in the reverberation chamber, the holding body may be configured to include a first holding body (in the example described above, the holding body A131) connected to the first stirring blade, a second holding body (in the example described above, the holding body A132) connected to the second stirring blade, and a first coupling (in the example described above, the coupling C2) connecting the first holding body and the second holding body, and the first insulator may be configured to be at least a part of the first coupling.

In addition, in the reverberation chamber, the holding body may be configured to include a second insulator (in the example described above, the insulator 15) electrically insulating the second stirring blade and the holding body from each other.

In addition, in the reverberation chamber, a bush (in the example described above, the bush BS2) made of an insulator may be configured to be used as at least a part of the second insulator.

Furthermore, in the reverberation chamber, a first spacer (in the example described above, the spacer S2) made of an insulator and disposed between the second stirring blade and the holding body may be configured to be used as at least a part of the second insulator, and the second stirring blade, the first spacer, and the holding body may be configured to be fixed using a fixing tool (in the example described above, the fixing tool SC) made of an insulator.

In addition, in the reverberation chamber, the holding body may be configured to include a third insulator (in the example described above, the insulator I1) electrically insulating the first stirring blade and the first wall face from each other.

Furthermore, in the reverberation chamber, the holding body may be configured to include a third holding body (in the example described above, the rotation shaft A0 of the motor M) electrically connected to the first wall face, a fourth holding body (in the example described above, the part A11) connected to the first stirring blade, and a second coupling (in the example described above, the coupling C1) connecting the third holding body and the fourth holding body, and the third insulator may be configured to be at least a part of the second coupling.

In addition, in the reverberation chamber, the holding body may be configured to include a fourth insulator (in the example described above, the insulator 14) electrically insulating the first stirring blade and the holding body from each other.

Furthermore, in the reverberation chamber, a bush (in the example described above, the bush BS2) made of an insulator may be configured to be used as at least a part of the fourth insulator.

In addition, in the reverberation chamber, a second spacer (in the example described above, the spacer S2) made of an insulator and disposed between the first stirring blade and the holding body may be configured to be used as at least a part of the fourth insulator, and the first stirring blade, the second spacer, and the holding body may be configured to be fixed using a fixing tool (in the example described above, the fixing tool SC) made of an insulator.

Furthermore, in the reverberation chamber, the holding body may be configured to include a fifth insulator (in the example described above, the coupling C1 (or a bearing in place of the coupling C1) of a case of being in contact with the first wall face W1, a part made of an insulator that is in contact with the holding body A1 in a part included in the first wall face W1,or the like) configured to connect the holding body and the first wall face.

In addition, in the reverberation chamber, a bearing electrically insulating the holding body and the first wall face from each other may be configured to be used as at least a part of the fifth insulator.

Furthermore, in the reverberation chamber, a third coupling (in the example described above, the coupling C1 of a case of being in contact with the first wall face W1 ) electrically insulating the holding body and the first wall face may be configured to be used as at least a part of the fifth insulator.

In addition, in the reverberation chamber, the holding body may be configured to be an insulator.

Furthermore, the reverberation chamber may be configured to further include a support body (in the example described above, the support body SB and the support body SB3) configured to support the holding body, and the support body may be configured to be disposed on a second wall face (in the example described above, the floor face of the reverberation chamber 1) of the reverberation chamber.

In addition, in the reverberation chamber, the holding body may be configured to be electrically insulated from the second wall face.

Furthermore, in the reverberation chamber, the support body may be configured to be an insulator.

In addition, the reverberation chamber may be configured to further include a sixth insulator (in the example described above, the insulator I6) electrically insulating the holding body and the support body from each other.

Furthermore, in the reverberation chamber, a bearing (in the example described above, the bearing B3) electrically insulating the holding body and the support body from each other may be configured to be used as at least a part of the sixth insulator.

In addition, in the reverberation chamber, a fixing tool (in the example described above, the fixing tool SC2) made of an insulator may be configured to be used as at least a part of the sixth insulator.

Furthermore, in the reverberation chamber, a third spacer (in the example described above, the spacer S4) made of an insulator and disposed between the holding body and the support body may be configured to be used as at least a part of the sixth insulator.

In addition, in the reverberation chamber, the support body may be configured to further include a seventh insulator (in the example described above, the insulator I6) electrically insulating the support body and the second wall face from each other.

Furthermore, in the reverberation chamber, a fourth spacer (in the example described above, the spacer S5) made of an insulator and disposed between the support body and the second wall face may be configured to be used as at least a part of the seventh insulator, and the support body, the fourth spacer, and the second wall face may be configured to be fixed using a fixing tool (in the example described above, the fixing tool fixing the spacer S5 to the floor face of the reverberation chamber 1) made of an insulator.

In addition, in the reverberation chamber, an end on a side opposite to an end connected to the first wall face out of two ends included in the holding body may be configured to be connected to the third wall face (in the example described above, the second wall face W2) of the reverberation chamber.

Furthermore, in the reverberation chamber, the first stirring blade may be configured to be electrically insulated from the third wall face.

In addition, in the reverberation chamber, the holding body may be configured to include an eighth insulator (in the example described above, the insulator I2) connecting the holding body and the third wall face.

Furthermore, in the reverberation chamber, a bearing (in the example described above, the bearing B1) electrically insulating the holding body and the third wall face from each other may be configured to be used as at least a part of the eighth insulator.

In addition, in the reverberation chamber, a fourth coupling (in the example described above, the coupling used in place of the bearing B1) electrically insulating the holding body and the third wall face from each other may be configured to be used as at least a part of the eighth insulator.

Furthermore, in the reverberation chamber, a fourth coupling (in the example described above, the coupling used in place of the bearing B1) electrically insulating the holding body and the third wall face from each other may be configured to be used as at least a part of the eighth insulator.

In addition, in the reverberation chamber, the holding body may be configured to be electrically insulated from the support body.

As above, although the embodiment of the present invention has been described in detail with reference to the drawings, a specific configuration is not limited to this embodiment, and changes, substitutions, omissions, and the like may be made without departing from the gist of the present invention.

| | |
|---|---|
| EXPLANATION OF REFERENCES | |
| 1, 1X | Reverberation chamber |
| 11 | Cavity resonator |
| 12 | Test device |
| 13, 13A, 13B, 13C, 13D, 13E, 13F, 13G, 13G1, 13G2, 13H, 13I | Electromagnetic stirrer |
| 14 | Control device |
| 121 | Signal generator |
| 122 | Amplifier |
| 123 | Directional coupler |
| 124 | Stirrer controller |
| 125 | Power measuring device |
| 126 | Antenna |
| 131 | First stirring blade |
| 132 | Second stirring blade |
| A0 | Rotation shaft |
| A1, A131, A132, H1, H2, H3 | Holding body |
| A11, A12, A13 | Part |
| B1, B2, B3 | Bearing |
| B11 | Housing bearing washer |
| B12 | Shaft bearing washer |
| B13 | Bearing fixing stand |
| BS1, BS2, BS3 | Bush |
| C1, C2 | Coupling |
| C11 | First member |
| C12 | Second member |
| F1, F2, F13, F14, F31, F32, F33, F34 | Flange |
| I1 , I2, 13, I4, I5, I6, I7 | Insulator |
| M | Motor |
| S1, S2, S3, S4, S5 | Spacer |
| SB, SB3 | Support body |
| SB1, SB31 | First support body |
| SB2, SB32 | Second support body |
| SC, SC2 | Fixing tool |
| TM | Device under test |
| W1 | First wall face |
| W2 | Second wall face |

1. A reverberation chamber comprising an electromagnetic stirrer,
wherein the electromagnetic stirrer includes:
a first stirring blade; and
a holding body disposed on a first wall face of the reverberation chamber, extending in a first direction intersecting with the first wall face, and configured to hold the first stirring blade, and
the first stirring blade is electrically insulated from the first wall face.

2. The reverberation chamber according to claim 1, wherein the electromagnetic stirrer further includes a second stirring blade aligned together with the first stirring blade in the first direction and disposed in the holding body.

3. The reverberation chamber according to claim 2, wherein the first stirring blade is electrically insulated from the second stirring blade.

4. A reverberation chamber comprising an electromagnetic stirrer,
wherein the electromagnetic stirrer includes:
a first stirring blade;
a second stirring blade; and
a holding body disposed on a first wall face of the reverberation chamber, extending in a first direction intersecting with the first wall face, configured to hold the first stirring blade and the second stirring blade to be aligned in the first direction, and
the first stirring blade is electrically insulated from the second stirring blade.

5. The reverberation chamber according to claim 2, wherein the holding body includes a first insulator electrically insulating the first stirring blade and the second stirring blade from each other.

6. The reverberation chamber according to claim 5,
wherein the holding body includes a first holding body connected to the first stirring blade, a second holding body connected to the second stirring blade, and a first coupling connecting the first holding body and the second holding body, and
the first insulator is at least a part of the first coupling.

7. The reverberation chamber according to claim 2, wherein the holding body includes a second insulator electrically insulating the second stirring blade and the holding body from each other.

8. The reverberation chamber according to claim 7, wherein a bush made of an insulator is used as at least a part of the second insulator.

9. The reverberation chamber according to claim 7,
wherein a first spacer made of an insulator and disposed between the second stirring blade and the holding body is used as at least a part of the second insulator, and
the second stirring blade, the first spacer, and the holding body are fixed using a fixing tool made of an insulator.

10. The reverberation chamber according to claim 8,
wherein a first spacer made of an insulator and disposed between the second stirring blade and the holding body is used as at least a part of the second insulator, and
the second stirring blade, the first spacer, and the holding body are fixed using a fixing tool made of an insulator.

11. The reverberation chamber according to claim 1, wherein the holding body includes a third insulator electrically insulating the first stirring blade and the first wall face from each other.

12. The reverberation chamber according to claim 11,
wherein the holding body includes a third holding body electrically connected to the first wall face, a fourth holding body connected to the first stirring blade, and a second coupling connecting the third holding body and the fourth holding body, and
the third insulator is at least a part of the second coupling.

13. The reverberation chamber according to claim 1, wherein the holding body includes a fourth insulator electrically insulating the first stirring blade and the holding body from each other.

14. The reverberation chamber according to claim 13, wherein a bush made of an insulator is used as at least a part of the fourth insulator.

15. The reverberation chamber according to claim 13,
wherein a second spacer made of an insulator and disposed between the first stirring blade and the holding body is used as at least a part of the fourth insulator, and
the first stirring blade, the second spacer, and the holding body are fixed using a fixing tool made of an insulator.

16. The reverberation chamber according to claim 14,
wherein a second spacer made of an insulator and disposed between the first stirring blade and the holding body is used as at least a part of the fourth insulator, and
the first stirring blade, the second spacer, and the holding body are fixed using a fixing tool made of an insulator.

17. The reverberation chamber according to claim 1, wherein the holding body is an insulator.

18. The reverberation chamber according claim 1, further comprising a support body configured to support the holding body,
wherein the support body is disposed on a second wall face of the reverberation chamber.

19. The reverberation chamber according to claim 18, wherein the holding body is electrically insulated from the second wall face.

20. The reverberation chamber according to claim 18, wherein the support body is an insulator.

21. The reverberation chamber according to claim 19, wherein the support body is an insulator.

22. The reverberation chamber according to claim 18, further comprising a sixth insulator electrically insulating the holding body and the support body from each other.

23. The reverberation chamber according to claim 19, further comprising a sixth insulator electrically insulating the holding body and the support body from each other.

24. The reverberation chamber according to claim 20, further comprising a sixth insulator electrically insulating the holding body and the support body from each other.

25. The reverberation chamber according to claim 18, wherein the holding body is electrically insulated from the support body.

26. An antenna device comprising the reverberation chamber according to claim 1.
